(19) United States
(12) Patent Application Publication
(10) Pub. No.: US 2025/0070912 A1
(43) Pub. Date: Feb. 27, 2025

(54) METHODS AND APPARATUS FOR DATA INFORMATION TRANSMISSION

(71) Applicant: ZTE Corporation, Shenzhen (CN)

(72) Inventors: Chulong LIANG, Shenzhen (CN); Wei ZHAO, Shenzhen (CN); Jin XU, Shenzhen (CN); Liguang LI, Shenzhen (CN); Guanghui YU, Shenzhen (CN); Jian KANG, Shenzhen (CN); Qiang FU, Shenzhen (CN)

(21) Appl. No.: 18/934,557

(22) Filed: Nov. 1, 2024

Related U.S. Application Data
(63) Continuation of application No. PCT/CN2022/129017, filed on Nov. 1, 2022.

(51) Int. Cl. H04L 1/00

(52) U.S. Cl. CPC H04L 1/0013

(57) ABSTRACT

Methods, apparatus, and systems that relate to rate matching scheme design for polar coding, PAC coding, or other pre-transformed polar coding are described. One example method includes determining, by a first node, an output bit sequence having E bits based on an input bit sequence having K bits, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein H, K and E are integers greater than 1, wherein a polar matrix G^{(N}^{ᵢ}⁾ is of size Nᵢ. The method also includes transmitting, by the first node, a signal including the output bit sequence to a second node.

### CROSS REFERENCE TO RELATED APPLICATIONS

This patent document is a continuation of and claims benefit of priority to International Patent Application No. PCT/CN2022/129017, filed on Nov. 1, 2022. The entire content of the before-mentioned patent application is incorporated by reference as part of the disclosure of this application.

### TECHNICAL FIELD

This invention is related to the channel coding technique in communication systems.

### BACKGROUND

Mobile telecommunication technologies are moving the world toward an increasingly connected and networked society. In comparison with the existing wireless networks, next generation systems and communication techniques will need to support a much wider range of use-case characteristics and provide a more complex and sophisticated range of access requirements and flexibilities.

Long-Term Evolution (LTE) is a standard for wireless communication for mobile devices and data terminals developed by 3rd Generation Partnership Project (3GPP). LTE Advanced (LTE-A) is a wireless communication standard that enhances the LTE standard. The 5th generation of wireless system, known as 5G, advances the LTE and LTE-A wireless standards and is committed to supporting higher data-rates, large number of connections, ultra-low latency, high reliability and other emerging business needs.

### SUMMARY

This patent document discloses techniques, among other things, rate matching design for polar coding, PAC coding and/or other pre-transformed polar coding schemes.

In one example aspect, a first digital communication method is disclosed. The method includes determining, by a first node, an output bit sequence having E bits based on an input bit sequence having K bits, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein H, K and E are integers greater than 1, wherein a polar matrix G^{(N}^{ᵢ}⁾ is of size Nᵢ; and transmitting, by the first node, a signal including the output bit sequence to a second node.

In another example aspect, another method of wireless communication is disclosed. The method includes receiving, by a second node, a signal including an output bit sequence having E bits from a first node; and determining, by the second node, an input bit sequence having K bits based on the signal, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein H, K and E are integers greater than 1, wherein a polar matrix G^{(N}^{ᵢ}⁾ is of size Nᵢ.

In yet another example aspect, a wireless communication device comprising a process that is configured or operable to perform the above-described methods is disclosed.

In yet another example aspect, a computer readable storage medium is disclosed. The computer-readable storage medium stores code that, upon execution by a processor, causes the processor to implement an above-described method.

### BRIEF DESCRIPTION OF THE DRAWING

FIG. 1 shows an example of factor graph of the polar matrix G⁽³²⁾.

FIG. 2A shows a diagram of polar coding with rate matching in 3GPP 5G standard.

FIG. 2B shows a diagram of PAC coding.

FIG. 3 shows a diagram for a convolution transform with either a convolution vector g or a convolution polynomial g(D).

FIG. 4A shows a first example for rate matching polar coding with repetition.

FIG. 4B shows a second example for rate matching polar coding with repetition.

FIG. 4C shows a third example for rate matching polar coding with repetition.

FIG. 4D shows a fourth example for rate matching polar coding with repetition.

FIG. 4E shows a fifth example for rate matching polar coding with repetition.

FIG. 4F shows a sixth example for rate matching polar coding with repetition.

FIG. 5 shows a diagram of a component polar coding.

FIG. 6 shows a diagram of a component pre-transformed polar coding.

FIG. 7 shows a specific example of a pre-transform defined by a recursive feedback polynomial q(D).

FIG. 8 shows another specific example of a pre-transform defined by both a generator polynomial g(D) and a recursive feedback polynomial q(D).

FIG. 9 shows an exemplary block diagram of a hardware platform that may be a part of a network device or a communication device.

FIG. 10 shows an example of network communication including a base station (BS) and user equipment (UE) based on some implementations of the disclosed technology.

FIG. 11 is a flowchart representation of a method for digital communication in accordance with one or more embodiments of the present technology.

FIG. 12 is a flowchart representation of another method for digital communication in accordance with one or more embodiments of the present technology.

### DETAILED DESCRIPTION

Headings for the various sections below are used to facilitate the understanding of the disclosed subject matter and do not limit the scope of the claimed subject matter in any way. Accordingly, one or more features of one section can be combined with one or more features of another section. Furthermore, 5G terminology is used for the sake of clarity of explanation, but the techniques disclosed in the present document are not limited to 5G technology only and may be used in wireless systems that implemented other protocols.

This application proposes methods and apparatuses related to rate matching schemes for pre-transformed polar coding in wireless communication systems.

In the fifth generation (5G) mobile communications standard of the 3^{rd} Generation Partnership Project (3GPP), low-density parity-check (LDPC) codes are used for data transmission. However, LDPC codes is worse than polar codes in short payload size (also called transport block size (TBS)). Also, LDPC codes have high error floors (at block error rate (BLER) of 0.0001). To fulfill the future ultra-reliable low latency communication (URLLC), we have to design more powerful channel codes.

Polarization-adjusted convolutional (PAC) codes can achieve finite-length bounds in moderate decoding complexity. PAC codes are a revolution of polar codes. As a result, PAC codes have code lengths with power of 2 (N=2ⁿ with positive integer n) as polar codes. However, to efficiently transmitting a payload (or transport block (TB)) in different wireless channel environments, it does not always have a code length of N=2ⁿ in time and frequency resources allocated by a base station (BS). As a result, rate matching schemes are needed for applying PAC codes in wireless communications. In this application, methods and apparatus for design in rate matching for polar coding, PAC coding, or other pre-transformed polar coding are proposed with good performance.

### INTRODUCTION

### Notations

GF(2) denotes the Galois field of size 2 with two elements “0” and “1”.

br(i) is the bit-reversal function.

floor(x) denotes the largest integer not greater than x.

ceil(x) denotes the smallest integer not less than x.

round(x) is the round function such that round(x) is the integer closest to x, for example, round(3.2)=3, round(4.8)=5, round(2.5)=3, round(−1.9)=−2, round(−3.4)=−3.

max(x,y) denotes the maximum value between x and y, i.e.,

$$max ( x , y ) = \{ \begin{matrix}x , & x \geq y , \\ y , & y > x .\end{matrix}$$

mod(x, y) denotes the remainder of x divided by y. For example, mod(5, 3)=2 and mod(3, 5)=3.

X_{i,j} denotes the element in the i-th row and j-th column of a matrix X, where a boldface capital letter is used to represent a matrix.

[x₀, x₁, . . . , x_{Y-1}] denotes a sequence (or a vector) of length Y containing elements x₀, x₁, . . . , x_{Y-1}. A boldface small letter x is used to represent a sequence (or a vector) [x₀, x₁, . . . , x_{Y-1}].

{x₀, x₁, . . . , x_{Y-1}} denotes a set with Y distinct elements x₀, x₁, . . . , x_{Y-1}, i.e., for any i≠j, xᵢ≠xⱼ.

<x₀, x₁, . . . , x_{Y-1}> denotes an ordered set with Y distinct elements x₀, x₁, . . . , x_{Y-1}, i.e., for any i≠j, xᵢ≠xⱼ. Let X=<x₀, x₁, . . . , x_{Y-1}>, X(i) denotes the i-th element xᵢ in the ordered set X.

For a set X, |X| denotes the set size, i.e., the number of elements in the set X.

Z_{N}={0, 1, . . . , N−2, N−1} denotes the integer set containing all non-negative integers smaller than N.

Indices for sequences, vectors, or matrices are starting from zero.

### Introduction to Polar Matrix

This section introduces some concepts of use of a polar matrix according to various embodiments.

We denote G^{(N)} as a polar transform matrix (or simply, polar matrix) with N rows and N columns, where N is power of 2, i.e., N=2ⁿ and n is a positive integer. n is called the order of the polar matrix of G^{(N)} and N is called the polar matrix size of G^{(N)}, i.e., G^{(N)} is of size N.

G^{(N)} can be one of the following:
1) G^{(N)}=(P⁽²⁾)^{⊗n};
2) G^{(N)}=B^{(N)}, (P⁽²⁾)^{⊗n};
3) G^{(N)}=P^{(N)};
4) G^{(N)}=B^{(N)}·P^{(N)};

Here, all the matrix operations are over GF(2), e.g.,

$${P}^{( N )} = [ \begin{matrix}{P}^{( N / 2 )} & 0 \\ {P}^{( N / 2 )} & {P}^{( N / 2 )}\end{matrix} ] , {P}^{( 2 )} = [ \begin{matrix}1 & 0 \\ 1 & 1\end{matrix} ] , {P}^{( 1 )} = [ 1 ] , {( {P}^{( 2 )} )}^{⊗ n}$$

is the n-th Kronecker power of the matrix P⁽²⁾, and B^{(N)} is a bit-reversal permutation matrix with N rows and N columns, 0 is an all-zero matrix with N/2 rows and N/2 columns.

Let B_{i,j}^{(N)} be the element at the i-th row and j-th column of the bit-reversal permutation matrix

$${B}_{i , j}^{( N )} = \{ \begin{matrix}1 , & j = br ( i ) , \\ 0 , & j \neq br ( i ) ,\end{matrix} for 0 \leq i < N and 0 \leq j < N ,$$

where br(i) is the bit-reversal function defined as

$$br ( i ) = \text{?} \cdot \text{?} and [ {b}_{n - 1} , {b}_{n - 2} , ... , {b}_{1} , {b}_{0} ]$$

$$\text{?} \text{indicates text missing or illegible when filed}$$

is the n-bit binary expansion of the integer i, i.e.,

$$i = \text{?} \cdot \text{?} .$$

$$\text{?} \text{indicates text missing or illegible when filed}$$

A sequence (or a vector) x of length N over GF(2) multiplying the polar matrix G^{(N)} over GF(2) is called polar transform on the sequence (vector) x. Denote y=x·G^{(N)}, where the vector-matrix multiplication is over GF(2). Then, y is the polar transform of x.

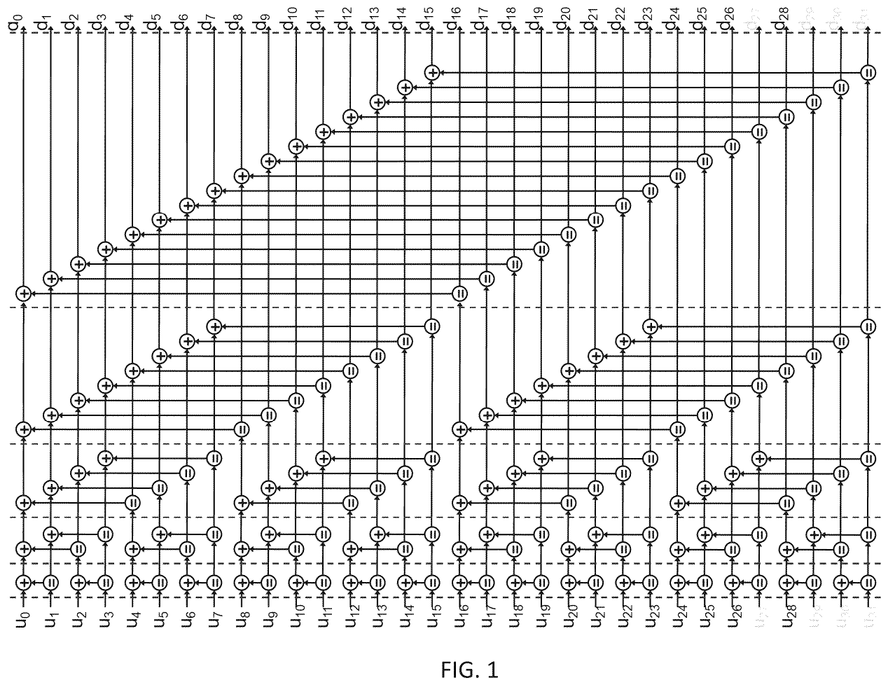

FIG. 1 shows the factor graph of the polar matrix G⁽³²⁾ of size N=32 and the matrix G⁽³²⁾ is shown below as:

### Introduction to 3GPP 5G Polar Coding

Some example embodiments of use of polar coding according to 3GPP 5G standard are disclosed in this section.

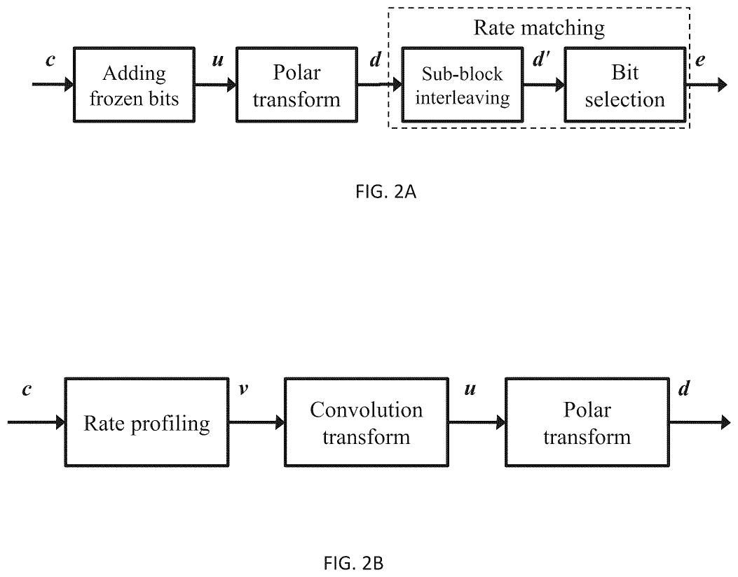

In the 3GPP 5G standard, polar codes are used in control channel transmission. The diagram of 5G polar coding with rate matching is shown in FIG. 2A.

Denote Q a data bit index set of size K, i.e., |Q|=K, where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , c_{E-2}, e_{E-1}] for the 5G polar coding with a polar matrix G^{(N)} includes the following operations, where K is the length of the input bit sequence, E is the length of the output bit sequence, K and E are positive integers, K<N, and K<E.

As shown in FIG. 2A, there are 3 main steps involved in the process: adding frozen bits, polar transform and rate matching. The rate matching step further includes sub-block interleaving and bit selection.
(1) Adding frozen bits: The adding-frozen-bits operation combines N-K zero bits with the input bit sequence c to form a polar transform input sequence u=[u₀, u₁, . . . , u_{N-2}, u_{N-1}] of length N according to the data bit index set Q.

The polar transform input sequence u is determined by the input bit sequence c, the data bit index set Q, and the polar matrix size N as follows:

```
k = 0;
For i = 0 to N-1
  If i ∈ Q
    uᵢ = cₖ;
    k = k + 1;
  Else
    uᵢ = 0;
  End if
End for
```

(2) Polar transform: The polar transform is converting a first length-N bit sequence into a second length-N bit sequence by multiplying the first length-N bit sequence and the polar matrix G^{(N)} over GF(2). A polar transform output bit sequence d=[d₀, d₁, . . . , d_{N-2}, d_{N-1}] of length N is determined by the polar transform input sequence u and the polar matrix G^{(N)} as d=u·G^{(N)}, where the vector-matrix multiplication is over GF(2).
(3) Rate matching: The rate matching of polar coding in 5G includes two operations: Sub-block interleaving and bit selection.
(3.1) Sub-block interleaving: An interleaving output bit sequence d′=[d′₀, d′₁, . . . , d′_{N-2}, d′_{N-1}] of length N is determined by a sub-block interleaver pattern π of length 32, the polar transform output bit sequence d, and the polar matrix size N as follows:

```
For i = 0 to N-1
  j = floor(32i/N);
  Jᵢ = πⱼx(N/32) + mod(i, N/32);
  d′ᵢ = d_{Ji};
End for
```

where π[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31], and J=[J₀, J₁, . . . , J_{N-2}, J_{N-1}] is an interleaver pattern of length N determined by the sub-block interleaver pattern π and the polar matrix size N. The interleaver pattern J is a permutation of the integer sequence [0, 1, 2, . . . , N−2, N−1].
(3.2) Bit selection: There are three types of bit selection named as repetition, puncturing and shortening. With the interleaving output bit sequence d′, the length of the input bit sequence K, the length of the output bit sequence E, and the polar matrix size N, the output bit sequence e is determined as follows:
Repetition: For E≥N, eₖ=d′_{mod(k,N)}, k=0, 1, 2, . . . , E−2, E−1.
Puncturing: For E<N and K/E≤ 7/16, eₖ=d′_{N-E+k}, k=0, 1, 2, . . . , E−2, E−1.
Shortening: For E<N and K/E> 7/16, eₖ=d′ₖ, k=0, 1, 2, . . . , E−2, E−1.

### Polarization-Adjusted Convolutional (PAC) Coding

Some examples embodiments of PAC coding are disclosed in this section.

PAC codes is a class of pre-transformed polar codes. Specifically, PAC codes are polar codes using convolution transform.

The diagram of PAC coding is shown in FIG. 2B. Denote Q a data bit index set of size K, i.e., |Q|=K, where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , e_{E-2}, e_{E-1}] by the polar matrix G^{(N)} includes the following operations, where K is the length of the input bit sequence, E is the length of the output bit sequence, K<N, K<E and K and E are positive integers.

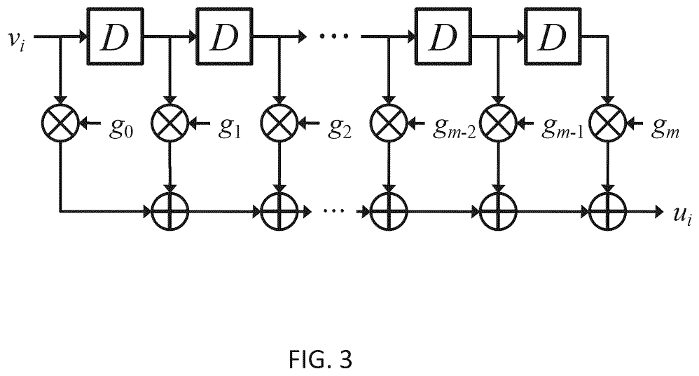

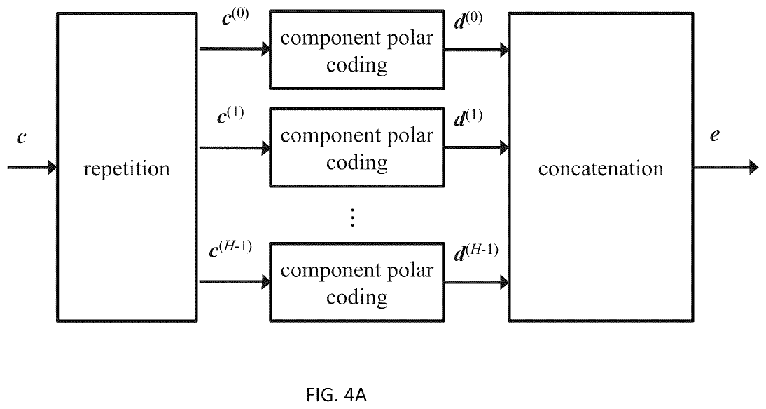

FIG. 3 discloses an example diagram for a convolution transform with either a convolution vector g=[g₀, g₁, . . . , gₘ] or a convolution polynomial g(D)=g₀+g₁·D+ . . . +gₘ₋₁·D^{m-1}+gₘ·D^{m} over GF(2).
(1) Rate profiling: The rate profiling is an operation same as the adding-frozen-bits operation in the 5G polar coding. Thus, the two terms “adding-frozen-bits” and “rate profiling” are used interchangeably to refer to the same operation in this document. The rate-profiling operation combines N-K zero bits with the input bit sequence c to form a rate-profiling output sequence v=[v₀, v₁, . . . , v_{N-2}, v_{N-1}] of length N according to the data bit index set Q. Specifically, the rate-profiling output bit sequence v is determined by the input bit sequence c, the data bit index set Q, and the polar matrix size N as follows.

```
k = 0;
For i = 0 to N-1
  If i ∈ Q
    vᵢ = cₖ;
    k = k + 1;
  Else
      vᵢ = 0;
  End if
End for
```

(2) Convolution transform: the convolution transform is an operation converting a convolution input bit sequence of length N into a convolution output bit sequence of length N by performing convolution on the convolution input bit sequence and a generator bit sequence g=[g₀, g₁, . . . , gₘ₋₁, gₘ] of length-(m+1) defining a generator polynomial g(D)=g₀+g₁·D+ . . . +gₘ₋₁·D^{m-1}+gₘ·D^{m} over GF(2), where m is the memory length of the convolution transform or equivalently the generator polynomial degree of the generator polynomial g(D) and D is a dummy variable representing delay in a digital circuit.
   The convolution transform with a generator polynomial g(D) is shown in FIG. 3. Specifically, a convolution transform output bit sequence u=[u₀, u₁, . . . , u_{N-2}, u_{N-1}] of length N is determined by the rate-profiling output bit sequence v, the generator polynomial g(D) (or equivalently the generator bit sequence g) and the polar matrix size N as follows, where vᵢ₋ₖ=0 for i<k.

```
For i = 0 to N-1
  uᵢ = 0;
  For k = 0 to m
    uᵢ = mod(uᵢ + gₖ · vᵢ₋ₖ, 2);
  End for
End for
```

Polar transform: The polar transform is the same as in the 5G polar coding. A polar transform output bit sequence d=[d₀, d₁, . . . , d_{N-2}, d_{N-1}] of length N is determined according to the convolution transform output bit sequence u and the polar matrix G^{(N)} as d=u·G^{(N)}, where the vector-matrix multiplication is over GF(2).

### INTRODUCTION TO EMBODIMENTS

This section discloses multiple examples related to rate matching for polar coding, PAC coding, or other pre-transformed polar coding with good performance.

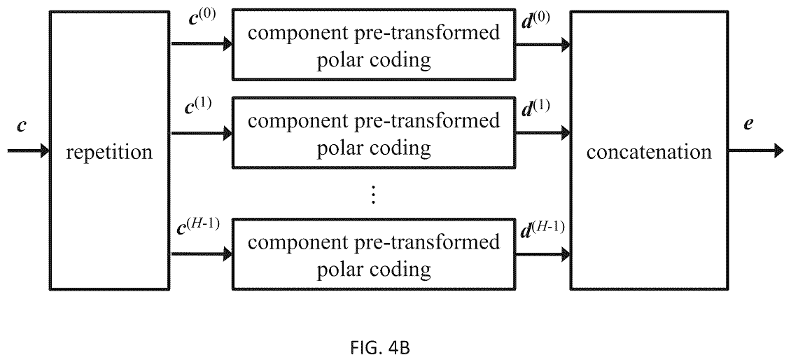

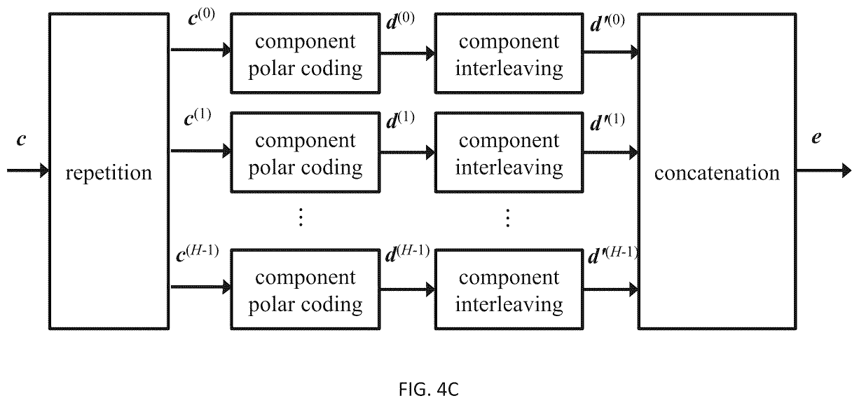

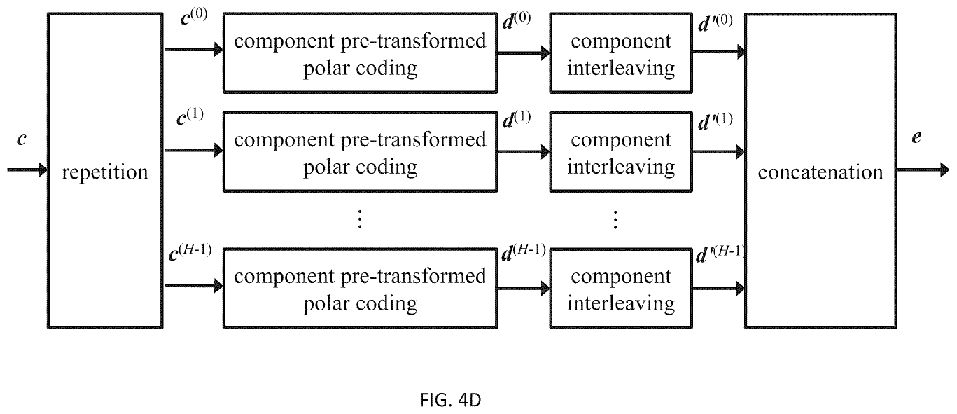

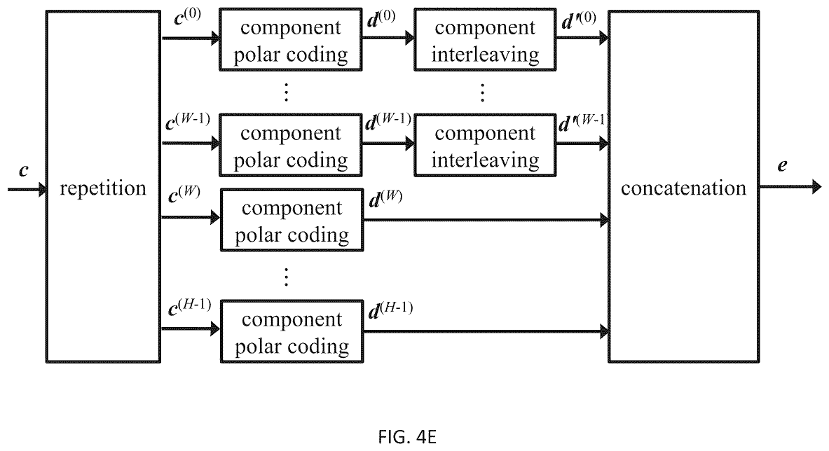

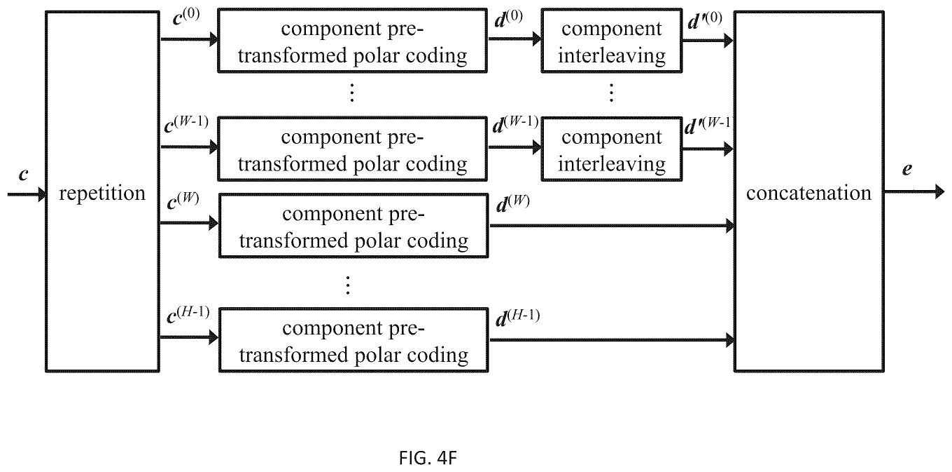

FIG. 4 shows diagrams of six example rate matching methods. The details of the examples will be explained in the following embodiments.

### Embodiment 1

This section discloses an encoding method in a wireless communication system.

In one example, a method of digital communication comprising determining, by a first node, an output bit sequence having E bits based on an input bit sequence having K bits, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein E, K, H are integers greater than 1, wherein a polar matrix G^{(N}^{ᵢ}⁾ is of size Nᵢ.

The method further comprises transmitting, by the first node, a signal including the output bit sequence to a second node.

In another example, a method of digital communication, comprising obtaining, by a first node, an input bit sequence c=[c₀, c₁, . . . , c_{K-1}]; and determining, by the first node, an output bit sequence e=[e₀, e₁, . . . , e_{E-1}] by performing at least one of the following: a repetition, H component polar coding based on H polar matrices G^{(N}^{₀}⁾, G^{(N}^{₁}⁾, . . . , G^{(N}^{_{H−1}}⁾, H component pre-transformed polar coding based on H polar matrices G^{(N}^{₀}⁾, G^{(N}^{₁}⁾, . . . , G^{(N}^{_{H−1}}⁾, W component interleaving, a concatenation; and transmitting, by the first node, a signal including the output bit sequence e to a second node.

Here, K is the input length of the input bit sequence c; E is the output length of the output bit sequence e; H is the number of component polar matrices; W is the number of component interleaving; K, E, and H are positive integers; K<E and H<E; H is an integer greater than one; W is an integer not greater than H; for h=0, 1, . . . , H−1, the h-th component polar coding is based on the h-th component polar matrix G^{(N}^{ₕ}⁾ and the h-th component pre-transformed polar coding is based on the h-th component polar matrix G^{(N}^{ₕ}⁾, wherein Nₕ is the h-th component polar matrix size and Nₕ=2ⁿ^{ₕ} is a power of two, wherein nₕ is a non-negative integer; the summation of H component polar matrix sizes is equal to the output length E, i.e., N₀+N₁+ . . . +N_{H-1}=E.

### Embodiment 2

This section discloses a decoding method used in a wireless communication system.

In one example, a method of digital communication, comprising receiving, by a second node, a signal including an output bit sequence having E bits from a first node. The method further comprises determining, by the second node, an input bit sequence having K bits based on the signal, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein E, K, H are integers greater than 1, wherein a polar matrix G^{(N}^{ᵢ}⁾ is of size Nᵢ.

In another example, a method of digital communication, comprising receiving, by a second node, a signal including an output bit sequence e=[e₀, e₁, . . . , e_{E-1}] sent by a first node; and determining, by the second node, an estimation of an input bit sequence c=[c₀, c₁, . . . , c_{K-1}].

Here, the output bit sequence e can be determined by the first node by at least one of the following: a repetition, H component polar coding based on H polar matrices G^{(N}^{₀}⁾, G^{(N}^{₁}⁾, . . . , G^{(N}^{_{H−1}}⁾, H component pre-transformed polar coding based on H polar matrices G^{(N}^{₀}⁾, G^{(N}^{₁}⁾, . . . , G^{(N}^{_{H−1}}⁾, W component interleaving, a concatenation; K is the input length of the input bit sequence c; E is the output length of the output bit sequence e; H is the number of component polar matrices; W is the number of component interleaving; K, E, and H are positive integers; K<E and H<E; H is an integer greater than one; W is an integer not greater than H; for h=0, 1, . . . , H−1, the h-th component polar coding is based on the h-th component polar matrix G^{(N}^{ₕ}⁾ and the h-th component pre-transformed polar coding is based on the h-th component polar matrix G^{(N}^{ₕ}⁾, wherein Nₕ is the h-th component polar matrix size and Nₕ=2ⁿ^{ₕ} is a power of two, wherein nₕ is a non-negative integer; the summation of H component polar matrix sizes is equal to the output length E, i.e., N₀+N₁+ . . . +N_{H-1}=E.

### Embodiment 3

This section discloses parameters for determining the output bit sequence e.

Embodiment 3 is based on the above embodiments.

In a first specific example, H=2 polar matrix sizes for an output length E=24 are N₀=16 and N₁=8. In a second specific example, H=3 polar matrix sizes for an output length E=24 is N₀=8, N₁=8, and N₂=8. In a third specific example, H=3 polar matrix sizes for an output length E=26 is N₀=16, N₁=8, and N₂=2.

The output bit sequence e is determined by the first node by at least one of the following:

the output bit sequence length K,

the output bit sequence length E,

H component polar matrix sizes N₀, N₁, . . . , N_{H-1},

H component repetition lengths K₀, K₁, . . . , K_{H-1},

H component repetition index sets R⁽⁰⁾, R⁽¹⁾, . . . , R^{(H-1)},

a first data bit index set Q={Q₀, Q₁, . . . , Q_{K-1}},

H component data bit index sets Q⁽⁰⁾, Q⁽¹⁾, . . . Q^{(H-1)},

H component generator polynomials g⁽⁰⁾(D), g⁽¹⁾(D), . . . , g^{(H-1)}(D) over GF(2),

H component recursive feedback polynomials q⁽⁰⁾(D), q⁽¹⁾(D), . . . , q^{(H-1)}(D) over GF(2),

H component polar matrices G^{(N}^{₀}⁾, G^{(N}^{₁}⁾, . . . , G^{(N}^{_{H−1}}⁾,

W component interleaver pattern J⁽⁰⁾, J⁽¹⁾, . . . , J^{(W-1)},

wherein, H is the number of component polar matrices; W is the number of component interleaver patterns and W is a non-negative integer not greater than H; for h=0, 1, . . . , H−1, the h-th component repetition length Kₕ is a positive integer and the h-th component repetition length Kₕ is smaller than the h-th component polar matrix size Nₕ.

Description of H Component Polar Matrix Sizes N₀, N₁, . . . , N_{H-1}

For h=0, 1, . . . , H−1, the component polar matrix sizes Nₕ is the polar matrix size of the h-th component polar matrix G^{(N}^{ₕ}⁾.

In some embodiments, all H component polar matrix sizes N₀, N₁, . . . , N_{H-1} are the same, i.e., N₀=N₁= . . . =N_{H-1}. A specific example with H=3 polar matrix sizes for an output length E=24 is N₀=N₁=N₂=8.

In some embodiments, not all H component polar matrix sizes N₀, N₁, . . . , N_{H-1} are the same, i.e., there exists h≠k such that Nₕ≠Nₖ. A specific example with H=3 polar matrix sizes for an output length E=24 are N₀=16, N₁=4 and N₂=4, wherein N₀≠N₁.

In some embodiments, all H component polar matrix sizes N₀, N₁, . . . , N_{H-1} are different, i.e., if h≠k, Nₕ≠Nₖ. A first specific example with H=2 polar matrix sizes for an output length E=24 are N₀=16 and N₁=8, wherein N₀≠N₁. A second specific example with H=3 polar matrix sizes for an output length E=26 is N₀=16, N₁=8, and N₂=2, wherein N₀≠N₁, N₀≠N₂, and N₁≠N₂.

Description of H Component Repetition Lengths K₀, K₁, . . . , K_{H-1}

In some embodiments, at least one of the H component repetition lengths K₀, K₁, . . . , K_{H-1} is equal to the input length K. A first specific example with H=3 polar matrix sizes and K=6, there are K₀=6, K₁=3 and K₂=1, wherein, K₀=K=6. A second specific example with H=3 polar matrix sizes and K=6, there are K₀=6, K₁=6 and K₂=1, wherein, K₀=K₁=K=6.

In some embodiments, all H component repetition lengths K₀, K₁, . . . , K_{H-1} are the same, i.e., K₀=K₁= . . . =K_{H-1}. A specific example with H=3 polar matrix sizes, there are K₀=K₁=K₂=2.

In some embodiments, not all H component repetition lengths K₀, K₁, . . . , K_{H-1} are the same, i.e., there exists h≠k such that Kₕ≠Kₖ. A specific example with H=3 polar matrix sizes, there are K₀=6, K₁=2 and K₂=2, wherein K₀≠K₁.

In some embodiments, all H component repetition lengths K₀, K₁, . . . , K_{H-1} are different, i.e., if h≠k, Kₕ≠Kₖ. A specific example with H=3 polar matrix sizes, there are K₀=6, K₁=3 and K₂=1, wherein K₀≠K₁, K₀≠K₂, and K₁≠K₂.

Description of component repetition index sets R⁽⁰⁾, R⁽¹⁾, . . . , R^{(H-1)}

For h=0, 1, . . . , H−1, the h-th component repetition set R^{(h)}={R₀^{(h)}, R₁^{(h)}, . . . , R_{K}_{ₕ}₋₁^{(h)}} has Kₕ elements, i.e., the size of the h-th component repetition set is |R^{(h)}|=Kₕ, wherein Kₕ is the h-th component repetition length. For h=0, 1, . . . , H−1, the h-th component repetition index set R^{(h)}={R₀^{(h)}, R₁^{(h)}, . . . , R_{K}_{ₕ}₋₁^{(h)}} is a subset of a first-type integer set Z_{K}={0, 1, . . . , K−2, K−1}, wherein, the first-type integer set Z_{K}={0, 1, . . . , K−2, K−1} comprises all non-negative integers smaller than K. In some embodiments, at least one of the H component repetition index sets R⁽⁰⁾, R⁽¹⁾, . . . , R^{(H-1)} is equal to a first-type integer set Z_{K}={0, 1, 2, . . . , K−1}, wherein the first-type integer set Z_{K}={0, 1, 2, . . . , K−1} comprises all non-negative integers smaller than K. In a specific example with K=6, E=24, H=2 polar matrix sizes N₀=16 and N₁=8, the H=2 component repetition index sets R⁽⁰⁾ and R⁽¹⁾ are R⁽⁰⁾=Z₆={0, 1, 2, 3, 4, 5} with K₀=K=6 and R⁽¹⁾={0, 1, 2} with K₁=3, respectively.

In some embodiments, none of H component repetition index sets R⁽⁰⁾, R⁽¹⁾, . . . , R^{(H-1)} is equal to a first-type integer set Z_{K}={0, 1, 2, . . . , K−1}, wherein the first-type integer set Z_{K}={0, 1, 2, . . . , K−1} comprises all non-negative integers smaller than K. In a specific example with K=6, E=24, H=3 polar matrix sizes N₀=16, N₁=4 and N₂=4, the H=3 component repetition index sets are R⁽⁰⁾={0, 1, 2, 3, 4} with K₀=5, R⁽¹⁾={5, 0} with K₁=2, and R⁽²⁾={1, 2} with K₁=2, respectively, wherein R⁽⁰⁾≠Z₆, R⁽¹⁾≠Z₆, and, R⁽²⁾≠Z₆, wherein, Z₆={0, 1, 2, 3, 4, 5}.

In some embodiments, for h=0, 1, . . . , H−2, the (h+1)-th component repetition index set R^{(h+1)} is a subset of the h-th component repetition index set R^{(h)}={R₀^{(h)}, R₁^{(h)}, . . . , R_{K}_{ₕ}₋₁^{(k)}}, i.e., R^{(h+1)} ⊆R^{(h)}. In a specific example with K=6, E=24, H=3 polar matrix sizes N₀=8, N₁=8, and N₂=8, the H=3 component repetition index sets R⁽⁰⁾, R⁽¹⁾, R⁽²⁾ are R⁽⁰⁾=Z₆={0, 1, 2, 3, 4, 5} with K₀=K=6, R⁽¹⁾={0, 2, 1} with K₁=3 and R⁽²⁾={0} with K₂=1, respectively, wherein, R⁽¹⁾⊆R⁽⁰⁾ and R⁽²⁾⊆R⁽¹⁾.

In some embodiments, for h, h′ being non-negative integers less than H and h not equal to h′, the intersection of the h-th component repetition index set R^{(h)} and the h′-th component repetition index set R^{(h′)} is an empty set, i.e., R^{(h)} ∩R^{(h′)}=Φ={ }, wherein (denotes the empty set. In a specific example with K=6, E=24, H=3 polar matrix sizes N₀=16, N₁=4 and N₂=4, the H=3 component repetition index sets are R⁽⁰⁾={0, 1} with K₀=2, R⁽¹⁾={2, 3} with K₁=2, and R⁽²⁾>={4, 5} with K₁=2, respectively.

In some embodiments, there exists h and k being non-negative integers less than H and h not equal to k (h≠k) such that the intersection of the h-th component repetition index set R^{(h)} and the k-th component repetition index set R^{(k)} is not an empty set, i.e., R^{(h)} ∩R^{(k)}≠Φ, wherein, Φ={ } is the empty set. In a first specific example with K=6, E=24, H=2 polar matrix sizes N₀=16 and N₁=8, the H=2 component repetition index sets R⁽⁰⁾ and R⁽¹⁾ are R⁽⁰⁾=Z₆={0, 1, 2, 3, 4, 5} with K₀=K=6 and R⁽¹⁾={0, 1, 2} with K₁=3, respectively, wherein, R⁽⁰⁾ ∩R⁽¹⁾={0, 1, 2} ≠{ }=Φ; wherein Φ denotes the empty set. In a second specific example with K=6, E=24, H=3 polar matrix sizes N₀=8, N₁=8, and N₂=8, the H=3 component repetition index sets R⁽⁰⁾, R⁽¹⁾, R⁽²⁾ are R⁽⁰⁾=Z₆={0, 1, 2, 3, 4, 5} with K₀=K=6, R⁽¹⁾={0, 1, 2} with K₁=3 and R⁽²⁾={4} with K₂=1, respectively, wherein, R⁽⁰⁾∩⁽¹⁾={0, 1, 2}≠Φ and R⁽⁰⁾ ∩R⁽²⁾={4}≠Φ; wherein Φ denotes the empty set. In a third specific example with K=6, E=26, H=3 polar matrix sizes N₀=16, N₁=8, and N₂=2, the H=3 component repetition index sets R⁽⁰⁾, R⁽¹⁾, R⁽²⁾ are R⁽⁰⁾={0, 1, 2, 3, 4} with K₀=5, R⁽¹⁾={0, 5} with K₁=2, and R⁽²⁾={4} with K₂=1, respectively, wherein, R⁽⁰⁾∩R⁽¹⁾={0}1≠Φ and R⁽⁰⁾∩R⁽²⁾={4}≠Φ; wherein Φ denotes the empty set. In some embodiments, all H component repetition index sets R⁽⁰⁾, R⁽¹⁾, . . . , R^{(H-1)} comprise an index k, wherein k is a non-negative integer. A specific example with H=3 component repetition index sets R⁽⁰⁾, R⁽¹⁾, R⁽²⁾ are R⁽⁰⁾={0, 1, 2, 3, 4} with K₀=5, R⁽¹⁾={5, 0, 2} with K₁=2, and R⁽²⁾={4, 0} with K₂=2, respectively, wherein H=3 component repetition index sets R⁽⁰⁾, R⁽¹⁾, R⁽²⁾ comprise an index k=0.

Description of component data bit index sets Q⁽⁰⁾, Q⁽¹⁾, . . . , Q^{(H-1)}

For h=0, 1, . . . , H−1, the h-th component data bit index set Q^{(h)}={Q₀^{(h)}, Q₁^{(h)}, . . . , Q_{K}_{ₕ}₋₁^{(h)}} has Kₕ elements, i.e., the size of the h-th component data bit index set is |Q^{(h)}|=Kₕ, wherein Kₕ is the h-th component repetition length. For h=0, 1, . . . , H−1, the h-th component data bit index set Q^{(h)}={Q₀^{(h)}, Q₁^{(h)}, . . . , Q_{K}_{ₕ}₋₁^{(h)}} is a subset of an h-th second-type integer set Z_{N}_{ₕ}={0, 1, . . . , Nₕ−2, Nₕ−1}, wherein, Nₕ is the h-th polar matrix size and the h-th second-type integer set Z_{N}_{ₕ}={0, 1, . . . , Nₕ−2, Nₕ−1} comprises all non-negative integers smaller than Nₕ. For h=0, 1, . . . , H−1, elements in the h-th data bit index set Qₕ are non-negative integers smaller than the polar matrix size Nₕ of the h-th component polar matrix G^{(N}^{ₕ}⁾. In some embodiments, at least one of the H component data bit index set sizes K₀, K₁, . . . , K_{H-1} is equal to the input length K. In a first specific example with K=6, E=24, H=2 polar matrix sizes N₀=16 and N₁=8, the H=2 component data bit index sets Q⁽⁰⁾ and Q⁽¹⁾ are Q⁽⁰⁾={12, 7, 11, 13, 14, 15} with K₀=K=6 and Q⁽¹⁾={12, 7, 11} with K₁=3, respectively, wherein, the 0-th component data bit index set Q₍₀₎={12, 7, 11, 13, 14, 15} is corresponding to the 0-th component polar matrix G^{(N}^{₀}⁾=G⁽¹⁶⁾ and the 1st component data bit index set Q⁽¹⁾={5, 6, 7} is corresponding to the 1^{st} component polar matrix G^{(N}^{₁}⁾=G⁽⁸⁾. In a second specific example with K=6, E=24, H=3 polar matrix sizes N₀=8, N₁=8, and N₂=8, the H=3 component data bit index sets Q⁽⁰⁾, Q⁽¹⁾, Q⁽²⁾ are Q⁽⁰⁾={2, 4, 3, 5, 6, 7} with K₀=K=6, Q⁽¹⁾={2, 4, 5} with K₁=3 and Q⁽²⁾={3} with K₂=1, respectively. In a third specific example with K=6, E=26, H=3 polar matrix sizes N₀=16, N₁=8, and N₂=2, the H=3 component repetition index sets Q⁽⁰⁾, Q⁽¹⁾, Q⁽²⁾ are Q⁽⁰⁾={7, 11, 13, 14, 15} with K₀=5, Q⁽¹⁾={6, 7} with K₁=2, and Q⁽²⁾={1} with K₂=1, respectively. In some embodiments, for some h, if k<k′, the k-th element Qₖ^{(h)} in the h-th component data bit index set Q^{(h)} is smaller than the k′-th element Q_{k′}^{(h)} z in the h-th component data bit index set Q^{(h)}, i.e., the h-th component data bit index set Q^{(h)} is sorted in ascending order according to index values with Q₀<Q₁< . . . <Q_{K-2}<Q_{K-1}. In some embodiments, for some h, if k<k′, the k-th element Qₖ^{(h)} in the h-th component data bit index set Q^{(h)} is greater than the k′-th element Q_{k′}^{(h)} in the h-th component data bit index set Q^{(h)}, i.e., the h-th component data bit index set Q^{(h)} is sorted in descending order according to index values with Q₀>Q₁> . . . >Q_{K-2}>Q_{K-1}. In some embodiments, for some h, if k<k′, the reliability of the Qₖ^{(h)}-th polarized sub-channel (denoted as W(Qₖ^{(h)}) corresponding to the h-th component polar matrix G^{(N}^{ₕ}⁾ is smaller than the reliability of the Q_{k′}^{(h)}-th polarized sub-channel (denoted as W(Q_{k′}^{(h)}) corresponding to the h-th component polar matrix G^{(N}^{ₕ}⁾, i.e., the h-th component data bit index set Q^{(h)} is sorted in ascending order according to the polarized sub-channel reliability with W(Q₀^{(h)})<W(Q₁^{(h)})< . . . <W(Q_{K}_{ₕ}₋₂^{(h)})<W(Q_{K}_{ₕ}₋₁^{(h)}). In some embodiments, for some h, if k<k′, the reliability of the Qₖ^{(h)}-th polarized sub-channel (denoted as W(Qₖ^{(h)})) corresponding to the h-th component polar matrix G^{(N}^{ₕ}⁾ is greater than the reliability of the Q_{k′}^{(h)}-th polarized sub-channel (denoted as W(Q_{k′}^{(h)})) corresponding to the h-th component polar matrix G^{(N}^{ₕ}⁾, i.e., the h-th component data bit index set Q^{(h)} is sorted in descending order according to the polarized sub-channel reliability with W(Q₀^{(h)})>W(Q₁^{(h)})> . . . >W(Q_{K}_{ₕ}₋₂^{(h)})>W(Q_{K}_{ₕ}₋₁^{(h)}).

### Description of First Data Bit Index Set Q

The first data bit index set Q={Q₀, Q₁, . . . , Q_{K-1}} has K elements, i.e., the size of the input data bit index set is |Q|=K, wherein K is the input length. The first data bit index set Q={Q₀, Q₁, . . . , Q_{K-1}} is a subset of a third-type integer set Z_{N}_{ₘ}={0, 1, . . . , Nₘ−2, Nₘ−1}, wherein, Nₘ is the maximum value among the H polar matrix sizes

$${N}_{0} , {N}_{1} , ... , {N}_{H - 1} , i . e . , {N}_{m} = {max}_{0 \leq h \leq H} {N}_{h}$$

and the third-type integer set Z_{N}_{ₘ}={0, 1, . . . , Nₘ−2, Nₘ−1} comprises all non-negative integers smaller than Nₘ. In some embodiments, at least one of the H component data bit index sets Q⁽⁰⁾, Q⁽¹⁾, . . . , Q^{(H-1)} is equal to the first data bit index set Q={Q₀, Q₁, . . . , Q_{K-1}}. In a first specific example with K=6, Nₘ=16, and E=24, a first data bit index set is Q={12, 7, 11, 13, 14, 15}. In a second specific example with K=6 and H=3 polar matrix sizes N₀=8, N₁=8 and N₂=8, we have Nₘ=max(max(N₀, N₁), N₂)=8, a data bit index set Q={2, 4, 3, 5, 6, 7}, and H=3 component data bit index set Q⁽⁰⁾={Q₀⁽⁰⁾, Q₀⁽⁰⁾, Q₂⁽⁰⁾, Q₃⁽⁰⁾, Q₄⁽⁰⁾, Q₅⁽⁰⁾}={2, 4, 3, 5, 6, 7}, Q⁽¹⁾={Q₀⁽¹⁾, Q₁⁽¹⁾, Q₂⁽¹⁾}={2, 4, 3}, Q⁽²⁾={Q₀⁽²⁾}{4}. In a third specific example with K=6 and H=3 polar matrix sizes N₀=16, N₁=8 and N₂=2, we have Nₘ=max(max(N₀, N₁), N₂)=16, and a data bit index set Q={12, 7, 11, 13, 14, 15}.
Description of Component Generator Polynomials g⁽⁰⁾(D), g⁽¹⁾(D), . . . , g^{(H-1)}(D)

In this document, a generator polynomial g(D)=g₀+g₁·D+ . . . +gₘ·D^{m} has a corresponding generator bit sequence g=[g₀, g₁, . . . , gₘ] of length m+1. The generator polynomial g(D) and its corresponding generator bit sequence g are used interchangeably in this document. For h=0, 1, . . . , H−1, the h-th component generator polynomial g^{(h)}(D)=g₀^{(h)}+g₁^{(h)}·D+ . . . +gₘ_{ₕ}^{(h)}·D^{m}^{ₕ} is corresponding to the h-th polar matrix G^{(N}^{ₕ}⁾ and can be any binary polynomial over GF(2), wherein mₕ is the memory length of the h-th component generator polynomial g^{(h)}(D) or the degree of the h-th component generator polynomial g^{(h)}(D). In some embodiments, H component generator polynomials g⁽⁰⁾(D), g⁽¹⁾(D), . . . , g^{(H-1)}(D) are identical to each other, i.e., g⁽⁰⁾(D)=g⁽¹⁾(D)= . . . =g^{(H-1)}(D). In some embodiments, H component generator polynomials g⁽⁰⁾(D), g⁽¹⁾(D), . . . , g^{(H-1)}(D) are not identical, i.e., there exists two integers h and h′ such that h≠h′ and g^{(h)}(D)≠g^{(h′)} (D). In a first specific example with H=1 and a memory length m₀=6, a 0-th component generator polynomial g⁽⁰⁾(D)=g₀⁽⁰⁾+g₁⁽⁰⁾·D+ . . . +gₘ_{₀}⁽⁰⁾·D^{m}^{₀}=g₀⁽⁰⁾+g₁⁽⁰⁾·D+g₂⁽⁰⁾·D²+g₃⁽⁰⁾·D³+g₄⁽⁰⁾·D⁴+g₅⁽⁰⁾·D⁵+g₆⁽⁰⁾·D⁶=1+D²+D³+D⁵+D⁶. In a second specific example with H=3, the H=3 component generator polynomials g⁽⁰⁾(D), g⁽¹⁾(D), g⁽²⁾(D) are the same, i.e., g⁽⁰⁾(D)=g⁽¹⁾(D)=g⁽²⁾(D)=1+D²+D³+D⁵+D⁶, wherein memory lengths m₀=m₁=m₂=6. In an third specific example with H=3 and memory lengths m₀=6, m₁=3, m₂=2, the 0-th component generator polynomial is g⁽⁰⁾(D)=g₀⁽⁰⁾+g₁⁽⁰⁾·D+ . . . +gₘ_{₀}⁽⁰⁾·Dₘ_{⁰}=g₀⁽⁰⁾+g₁⁽⁰⁾·D+g₂⁽⁰⁾·D²+g₃⁽⁰⁾·D³+g₄⁽⁰⁾·D⁴+g₂⁽⁰⁾·D⁵+g₆⁽⁰⁾·D₆=1+D²+D³+D⁵+D⁶, the 1^{st} component generator polynomial is g⁽¹⁾ (D)=g₀⁽¹⁾+g₁⁽¹⁾·D+ . . . +gₘ_{₁}⁽¹⁾·D^{m}^{₁}=g₀⁽¹⁾+g₁⁽¹⁾·D+g₂⁽¹⁾·D²+g₃⁽¹⁾·D³=1+D+D³, and the 2^{nd} component generator polynomial is g⁽²⁾(D)=g₀⁽²⁾+g₁⁽²⁾·D+ . . . +gₘ_{₂}⁽²⁾·D^{m}^{₂}=g₀⁽²⁾+g₁⁽²⁾·D+g₂⁽²⁾·D²=1+D². More specific examples for a component generator polynomial g^{(h)}(D)=g^{(h)}₀+g^{(h)}₁·D+ . . . +g^{(h)}ₘ·D^{m} are as follows:

$$For m = 1 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D = 1 + D ; \qquad ( 1 )$$

$$For m = 2 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} = 1 + {D}^{2} ; \qquad ( 2 )$$

$$For m = 3 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + {{g}^{( h )}}_{3} \cdot {D}^{3} = 1 + D + {D}^{2} + {D}^{3} ; \qquad ( 3 )$$

$$For m = 4 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + {{g}^{( h )}}_{3} \cdot {D}^{3} + {{g}^{( h )}}_{4} \cdot {D}^{4} = 1 + D + {D}^{2} + {D}^{4} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + {{g}^{( h )}}_{3} \cdot {D}^{3} + {{g}^{( h )}}_{4} \cdot {D}^{4} = 1 + {D}^{2} + {D}^{3} + {D}^{4} ; \qquad ( 4 )$$

$$For m = 5 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{5} \cdot {D}^{5} = 1 + D + {D}^{3} + {D}^{5} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{5} \cdot {D}^{5} = 1 + {D}^{2} + {D}^{4} + {D}^{5} ; \qquad ( 5 )$$

$$For m = 6 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{6} \cdot {D}^{6} = 1 + {D}^{6} ; \qquad ( 6 )$$

$$For m = 7 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{7} \cdot {D}^{7} = 1 + {D}^{3} + {D}^{5} + {D}^{7} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{7} \cdot {D}^{7} = 1 + {D}^{2} + {D}^{4} + {D}^{7} ; \qquad ( 7 )$$

$$For m = 8 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{8} \cdot {D}^{8} = 1 + {D}^{4} + {D}^{8} ; \qquad ( 8 )$$

$$For m = 9 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{9} \cdot {D}^{9} = 1 + {D}^{3} + {D}^{4} + {D}^{5} + {D}^{7} + {D}^{9} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{9} \cdot {D}^{9} = 1 + {D}^{2} + {D}^{4} + {D}^{5} + {D}^{6} + {D}^{9} ; \qquad ( 9 )$$

$$For m = 10 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{10} \cdot {D}^{10} = 1 + {D}^{2} + {D}^{6} + {D}^{7} + {D}^{10} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{10} \cdot {D}^{10} = 1 + {D}^{3} + {D}^{4} + {D}^{8} + {D}^{10} ; \qquad ( 10 )$$

$$For m = 11 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{11} \cdot {D}^{11} = 1 + D + {D}^{2} + {D}^{4} + {D}^{8} + {D}^{10} + {D}^{11} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{11} \cdot {D}^{11} = 1 + D + {D}^{3} + {D}^{7} + {D}^{9} + {D}^{10} + {D}^{11} ; \qquad ( 11 )$$

$$For m = 12 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{12} \cdot {D}^{12} = 1 + {D}^{2} + {D}^{5} + {D}^{6} + {D}^{7} + {D}^{8} + {D}^{9} + {D}^{10} + {D}^{11} + {D}^{12} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{12} \cdot {D}^{12} = 1 + D + {D}^{2} + {D}^{3} + {D}^{4} + {D}^{5} + {D}^{6} + {D}^{7} + {D}^{10} + {D}^{12} ; \qquad ( 12 )$$

$$For m = 13 , {g}^{( h )} ( D ) = {{g}^{( h )}}_{0} + {{g}^{( h )}}_{1} \cdot D + … + {{g}^{( h )}}_{m} \cdot {D}^{m} = {g}_{0} + {g}_{1} \cdot D + {g}_{2} \cdot {D}^{2} + … + {g}_{13} \cdot {D}^{13} = 1 + D + {D}^{4} + {D}^{5} + {D}^{9} + {D}^{10} + {D}^{13} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{13} \cdot {D}^{13} = 1 + {D}^{3} + {D}^{4} + {D}^{8} + {D}^{9} + {D}^{12} + {D}^{13} ; \qquad ( 13 )$$

$$For m = 14 , {g}^{( h )} ( D ) = {{g}^{( h )}}_{0} + {{g}^{( h )}}_{1} \cdot D + … + {{g}^{( h )}}_{m} \cdot {D}^{m} = {g}_{0} + {g}_{1} \cdot D + {g}_{2} \cdot {D}^{2} + … + {g}_{14} \cdot {D}^{14} = 1 + D + {D}^{2} + {D}^{7} + {D}^{8} + {D}^{10} + {D}^{12} + {D}^{14} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{14} \cdot {D}^{14} = 1 + {D}^{2} + {D}^{4} + {D}^{6} + {D}^{7} + {D}^{12} + {D}^{13} + {D}^{14} ; \qquad ( 14 )$$

$$For m = 15 , {g}^{( h )} ( D ) = {{g}^{( h )}}_{0} + {{g}^{( h )}}_{1} \cdot D + … + {{g}^{( h )}}_{m} \cdot {D}^{m} = {g}_{0} + {g}_{1} \cdot D + {g}_{2} \cdot {D}^{2} + … + {g}_{15} \cdot {D}^{15} = 1 + D + {D}^{4} + {D}^{6} + {D}^{7} + {D}^{8} + {D}^{9} + {D}^{15} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{15} \cdot {D}^{15} = 1 + {D}^{6} + {D}^{7} + {D}^{8} + {D}^{9} + {D}^{11} + {D}^{14} + {D}^{15} ; \qquad ( 15 )$$

$$For m = 16 , {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{16} \cdot {D}^{16} = 1 + {D}^{2} + {D}^{4} + {D}^{6} + {D}^{8} + {D}^{13} + {D}^{14} + {D}^{16} and {g}^{( h )} ( D ) = {{g}^{( h )}}_{0} + {{g}^{( h )}}_{1} \cdot D + … + {{g}^{( h )}}_{m} \cdot {D}^{m} = {{g}^{( h )}}_{0} + {{g}^{( h )}}_{1} \cdot D + {{g}^{( h )}}_{2} \cdot {D}^{2} + … + {{g}^{( h )}}_{16} \cdot {D}^{16} = 1 + {D}^{2} + {D}^{3} + {D}^{8} + {D}^{10} + {D}^{12} + {D}^{14} + {D}^{16} ; \qquad ( 16 )$$

wherein m is the memory length.

Description of recursive feedback polynomials q⁽⁰⁾(D), q⁽¹⁾(D), . . . , p^{(H-1)}(D)

In this document, a recursive feedback polynomial q(D)=q₀+q₁·D+ . . . +qₘ·D^{m} has a corresponding recursive feedback bit sequence q=[q₀, q₁, . . . , qₘ] of length m+1. The recursive feedback polynomial q(D) and its corresponding recursive feedback bit sequence q are used interchangeably in this document.

For h=0, 1, . . . , H−1, the h-th component recursive feedback polynomial q^{(h)}(D)=q₀^{(h)}+q₁^{(h)}·D+ . . . +qₘ_{ₕ}^{(h)}·D^{m}^{ₕ} is corresponding to the h-th polar matrix G^{(N}^{ₕ}⁾ and can be any binary polynomial over GF(2), wherein mₕ is the memory length of the h-th component recursive feedback polynomial q^{(h)}(D) or the degree of the h-th component recursive feedback polynomial q^{(h)}(D). In some embodiments, H component recursive feedback polynomials q⁽⁰⁾(D), q⁽¹⁾(D), . . . , q^{(H-1)}(D) are identical to each other, i.e., q⁽⁰⁾(D)=q⁽¹⁾(D)= . . . =q^{(H-1)}(D). In some embodiments, H component recursive feedback polynomials q⁽⁰⁾(D), q⁽¹⁾(D), . . . , q^{(H-1)}(D) are not identical, i.e., there exists two integers h and h′ such that h≠h′ and q^{(h)}(D)≠q^{(h′)}(D). In a first specific example with H=1 and a memory length m₀=6, a 0-th recursive feedback polynomial is q⁽⁰⁾(D)=q₀⁽⁰⁾+q₁⁽⁰⁾·D+ . . . +qₘ_{₀}⁽⁰⁾·D^{m}^{₀}=q₀⁽⁰⁾+q₁⁽⁰⁾·D+q₂⁽⁰⁾·D²+q₃⁽⁰⁾·D³+q₄⁽⁰⁾·D⁴+q₅⁽⁰⁾·D⁵+q₆⁽⁰⁾·D₆=1+D²+D⁴+D⁵+D⁶. In a second specific example with H=3, H=3 recursive feedback polynomials q⁽⁰⁾(D), q⁽¹⁾(D), q⁽²⁾(D) are the same and q⁽⁰⁾(D)=q⁽¹⁾(D)=q⁽²⁾(D)=1+D²+D⁴+D⁵+D⁶, wherein memory lengths m₀=m₁=m₂=6. In an third specific example with H=2 and memory lengths m₀=6 and m₁=3, a 0-th recursive feedback polynomial is q⁽⁰⁾(D)=q₀⁽⁰⁾+q₁⁽⁰⁾·D+ . . . +qₘ_{₀}⁽⁰⁾·D^{m}^{₀}=q₀⁽⁰⁾+q₁⁽⁰⁾·D+q₂⁽⁰⁾·D²+q₃⁽⁰⁾·D³+q₄⁽⁰⁾·D⁴+q₅⁽⁰⁾·D⁵+q₆⁽⁰⁾·D⁶=1+D²+D⁴+D⁵+D⁶ and a 1^{st} recursive feedback polynomial is q⁽¹⁾(D)=q₀⁽¹⁾+q⁽¹⁾·D+ . . . +qₘ_{₁}⁽¹⁾·D^{m}^{₁}=q₀⁽¹⁾+q₁⁽¹⁾·D+q₂⁽¹⁾·D²+q₃⁽¹⁾·D³=1+D²+D³.

Description of Component Interleaver Patterns J⁽⁰⁾, J⁽¹⁾, . . . , J^{(W-1)}

For h=0, 1, . . . , W−1, the h-th component interleaver pattern J^{(h)}=[J₀^{(h)}, J₁^{(h)}, . . . , J_{N}_{ₕ}₋₁^{(h)}] is of size Nₕ, wherein, Nₕ is the h-th polar matrix size and J^{(h)} is a permutation of the sequence [0, 1, 2, . . . , Nₕ−1]. A first specific example with H=2, W=2, N₀=16, N₁=8, a 0-th component interleaver pattern J⁽⁰⁾=[J₀⁽⁰⁾, J₁⁽⁰⁾, . . . , J_{N}_{₀}₋₁⁽⁰⁾]=[J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾, J₈⁽⁰⁾, J₉⁽⁰⁾, J₁₀⁽⁰⁾, J₁₁⁽⁰⁾, J₁₂⁽⁰⁾, J₁₃⁽⁰⁾, J₁₄⁽⁰⁾, J₁₅⁽⁰⁾ ]=[0, 1, 2, 4, 3, 5, 6, 7, 8, 9, 10, 11, 12, 13, 14, 15] is a permutation of the array [0, 1, 2, 3, 4, 5, 6, 7, 8, 9, 10, 11, 12, 13, 14, 15] and a 1^{st} component interleaver pattern J⁽¹⁾=[J₀⁽¹⁾, J₁⁽¹⁾, . . . , J_{N}_{₁}₋₁⁽¹⁾]=[J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾ ]=[0, 1, 2, 4, 3, 5, 6, 7] is a permutation of the array [0, 1, 2, 3, 4, 5, 6, 7]. A second specific example with H=3, W=2, N₀=N₁=N₂=8, a 0-th component interleaver pattern J⁽⁰⁾=[J₀⁽⁰⁾, J₁⁽⁰⁾, . . . , J_{N}_{₀}₋₁⁽⁰⁾]=[J₀⁽⁰⁾, J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾ ]=[0, 1, 2, 3, 4, 6, 7, 5] is a permutation of the array [0, 1, 2, 3, 4, 5, 6, 7] and a 1^{st} component interleaver pattern J⁽⁰⁾=[J₀⁽¹⁾, J₁⁽¹⁾, . . . , J_{N}_{₁}₋₁⁽¹⁾]=[J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾ ]=[0, 1, 2, 4, 3, 5, 6, 7] is a permutation of the array [0, 1, 2, 3, 4, 5, 6, 7]. A third specific example with H=3, W=3, N₀=16, N₁=8, and N₂=2, a 0-th component interleaver pattern J⁽⁰⁾=[J₀⁽⁰⁾, J₁⁽⁰⁾, . . . , J_{N}_{₀}₋₁⁽⁰⁾]=[J₀⁽⁰⁾, J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾, J₈⁽⁰⁾, J₉⁽⁰⁾, J₁₀⁽⁰⁾, J₁₁⁽⁰⁾, J₁₂⁽⁰⁾, J₁₃⁽⁰⁾, J₁₄⁽⁰⁾, J₁₅⁽⁰⁾ ]=[0, 1, 2, 4, 3, 5, 6, 7, 8, 9, 10, 11, 12, 13, 14, 15] is a permutation of the array [0, 1, 2, 3, 4, 5, 6, 7, 8, 9, 10, 11, 12, 13, 14, 15], a 1^{st} component interleaver pattern J⁽¹⁾=[J₀⁽¹⁾, J₁⁽¹⁾, . . . , J_{N}_{₁}₋₁⁽¹⁾]=[J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾ ]=[5, 4, 7, 1, 6, 0, 2, 3] is a permutation of the array [0, 1, 2, 3, 4, 5, 6, 7], and a 2^{nd} component interleaver pattern J⁽²⁾=[J₀⁽²⁾, J₁⁽²⁾, . . . , J_{N}_{₂}₋₁⁽²⁾]=[J₀⁽²⁾, J₁⁽²⁾ ]=[1, 0] is a permutation of the array [0, 1]. A fourth specific example with H=3, W=1, N₀=8, N₁=16, and N₂=2, a 2^{nd} component interleaver pattern J⁽⁰⁾=[J₀⁽⁰⁾, J₁⁽⁰⁾, J_{N}_{₀}₋₁⁽⁰⁾]=[J₀⁽²⁾, J₁⁽²⁾ ][1, 0] is a permutation of the array [0, 1].

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component polar coding by obtaining the h-th component repetition output bit sequence c^{(h)}=[c₀^{(h)}, c₁^{(h)}, . . . , c_{K}_{ₕ}₋₁^{(h)}] and determining an h-th component polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, the first node performs a concatenation by obtaining the H component polar coding output bit sequences d⁽⁰⁾, d⁽¹⁾, d⁽²⁾, . . . , d^{(H-1)} and determining the output bit sequence e=[e₀, e₁, . . . , e_{E-1}] of length E, wherein, a specific example is shown in FIG. 4A.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component pre-transformed polar coding by obtaining the h-th component repetition output bit sequence c^{(h)}=[c₀^{(h)}, c₁^{(h)}, . . . , c_{K}_{ₕ}₋₁^{(h)}] and determining an h-th component pre-transformed polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, the first node performs a concatenation by obtaining the H component pre-transformed polar coding output bit sequences d⁽⁰⁾, d⁽¹⁾, d⁽²⁾, . . . , d^{(H-1)} and determining the output bit sequence e=[e₀, e₁, . . . , e_{E-1}] of length E, wherein, a specific example is shown in FIG. 4B.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component polar coding by obtaining the h-th component repetition output bit sequence c^{(h)}=[c₀^{(h)}, c₁^{(h)}, . . . , c_{K}_{ₕ}₋₁^{(h)}] and determining an h-th component polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, the number of component interleaver patterns W is equal to the number of component polar matrices H and for h=0, 1, 2, . . . , H−1, the first node performs a component interleaving by obtaining the h-th component polar coding output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)}=[d′₀^{(h)}, d′₁^{(h)}, . . . , d′_{N}_{ₕ}₋₁^{(h)}] of length Nₕ, wherein Nₕ is the polar matrix size of G^{(N}^{ₕ}⁾. In some embodiments, the first node performs a concatenation by obtaining the W=H component interleaving output bit sequences d′⁽⁰⁾, d′⁽¹⁾, d′⁽²⁾, . . . , d′^{(H-1)} and determining the output bit sequence e=[e₀, e₁, . . . , e_{E-1}] of length E, wherein, a specific example is shown in FIG. 4C.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component pre-transformed polar coding by obtaining the h-th component repetition output bit sequence c^{(h)}=[c₀^{(h)}, c₁^{(h)}, . . . , c_{K}_{ₕ}₋₁^{(h)}] and determining an h-th component pre-transformed polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, the number of component interleaver patterns W is equal to the number of component polar matrices H and for h=0, 1, 2, . . . , H−1, the first node performs a component interleaving by obtaining the h-th component pre-transformed polar coding output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)} [d′₀^{(h)}, d′₁^{(h)}, . . . , d′_{N}_{ₕ}₋₁^{(h)}] _of length Nₕ, wherein Nₕ is the polar matrix size of G^{(N}^{ₕ}⁾. In some embodiments, the first node performs a concatenation by obtaining the W=H component interleaving output bit sequences d′⁽⁰⁾, d′⁽¹⁾, d′⁽²⁾, . . . , d′^{(H-1)} and determining the output bit sequence e=[e₀, e₁, . . . , e_{E-1}] of length E, wherein, a specific example is shown in FIG. 4D.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component polar coding by obtaining the h-th component repetition output bit sequence c^{(h)}=[c₀^{(h)}, c₁^{(h)}, . . . , c_{K}_{ₕ}₋₁^{(h)}] and determining an h-th component polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, for h=0, 1, . . . , W−1, the first node performs a component interleaving by obtaining the h-th component polar coding output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)}=[d′₀^{(h)}, d′₁^{(h)}, . . . , d′_{N}_{ₕ}₋₁^{(h)}] of length Nₕ, wherein Nₕ is the polar matrix size of G^{(N}^{ₕ}⁾. In some embodiments, the first node performs a concatenation by obtaining the W component interleaving output bit sequences d′⁽⁰⁾, d′⁽¹⁾, d′⁽²⁾, . . . , d′^{(W-1)} and the H-W component polar coding output bit sequences d^{(W)}, d^{(W+1)}, . . . , d^{(H-1)} to determine the output bit sequence e=[e₀, e₁, . . . , e_{E-1}] of length E, wherein, a specific example is shown in FIG. 4E.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ. In some embodiments, for h=0, 1, 2, . . . , H−1, the first node performs a component pre-transformed polar coding by obtaining the h-th component repetition output bit sequence c^{(h)}=[c₀^{(h)}, c₁^{(h)}, . . . , c_{K}_{ₕ}₋₁^{(h)}] and determining an h-th component pre-transformed polar coding output bit sequence d^{(h)}=[d₀^{(h)}, d₁^{(h)}, . . . , d_{N}_{ₕ}₋₁^{(h)}] of length Nₕ corresponding to the h-th component polar matrix G^{(N}^{ₕ}⁾, wherein Nₕ is the polar matrix size of G^{(N}^{ₕ}⁾. In some embodiments, for h=0, 1, . . . , W−1, the first node performs a component interleaving by obtaining the h-th component pre-transformed polar coding output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)}=[d′₀^{(h)}, d′₁^{(h)}, . . . , d′_{N}_{ₕ}₋₁^{(h)}] wherein Nₕ is the polar matrix size of G^{(N}^{ₕ}⁾. In some embodiments, the first node performs a concatenation by obtaining the W component interleaving output bit sequences d′⁽⁰⁾, d′⁽¹⁾, d′⁽²⁾, . . . , d′^{(W-1)} and the H-W component pre-transformed polar coding output bit sequences d^{(W)}, d^{(W+1)}, . . . , d^{(H-1)} to determine the output bit sequence e=[e₀, e₁, . . . , e_{E-1}] of length E, wherein, a specific example is shown in FIG. 4F.

In some embodiments, the first node performs a component interleaving on W bit sequences of the H component polar coding output bit sequences d⁽⁰⁾, d⁽¹⁾, d⁽²⁾, . . . , d^{(H-1)} to determine W component interleaving output bit sequences, wherein W is a non-negative integer not greater than H. In a first specific example with H=3 component polar coding output bit sequences d⁽⁰⁾, d⁽¹⁾, d⁽²⁾ and W=2, the first node performs a component interleaving on W=2 component polar coding output bit sequences d⁽⁰⁾, d⁽²⁾ to determine W=2 component interleaving output bit sequences d′⁽⁰⁾, d′⁽²⁾, wherein the 0-th component interleaving output bit sequences d′⁽⁰⁾ is corresponding to the 0-th component polar coding output bit sequences d⁽⁰⁾; the 2^{nd} component interleaving output bit sequences d′⁽²⁾ is corresponding to the 2^{nd} component polar coding output bit sequences d⁽²⁾. In a second specific example with H=3 component polar coding output bit sequences d⁽⁰⁾, d⁽¹⁾, d⁽²⁾ and W=1, the first node performs a component interleaving on W=1 component polar coding output bit sequence d⁽¹⁾ to determine W=1 component interleaving output bit sequences d′⁽¹⁾, wherein the 1^{st} component interleaving output bit sequence d′⁽¹⁾ is corresponding to the 1^{st} component polar coding output bit sequence d⁽¹⁾.

In some embodiments, the first node performs a component interleaving on W bit sequences of the H component pre-transformed polar coding output bit sequences d⁽⁰⁾, d⁽¹⁾, d⁽²⁾, . . . , d^{(H-1)} to determine W component interleaving output bit sequences, wherein W is a non-negative integer not greater than H. In a first specific example with H=3 component pre-transformed polar coding output bit sequences d⁽⁰⁾, d⁽¹⁾, d⁽²⁾ and W=2, the first node performs a component interleaving on W=2 component pre-transformed polar coding output bit sequences d⁽⁰⁾, d⁽²⁾ to determine W=2 component interleaving output bit sequences d′⁽⁰⁾, d′⁽²⁾, wherein the 0-th component interleaving output bit sequences d′⁽⁰⁾ is corresponding to the 0-th component pre-transformed polar coding output bit sequences d⁽⁰⁾; the 2^{nd} component interleaving output bit sequences d′⁽²⁾ is corresponding to the 2^{nd} component pre-transformed polar coding output bit sequences d⁽²⁾. In a second specific example with H=3 component pre-transformed polar coding output bit sequences d⁽⁰⁾, d⁽¹⁾, d⁽²⁾ and W=1, the first node performs a component interleaving on W=1 component pre-transformed polar coding output bit sequences d⁽¹⁾ to determine W=1 component interleaving output bit sequence d′⁽¹⁾, wherein the 1^{st} component interleaving output bit sequence d′⁽¹⁾ is corresponding to the 1^{st} component pre-transformed polar coding output bit sequence d⁽¹⁾.

### Embodiment 4

This section discloses examples involving a concatenation block that may perform a concatenation operation.

Embodiment 4 is based on the embodiments disclosed above.

The input of a concatenation operation can be based on the input sequence c.

In one example, a concatenation block can relate to one or more component polar coding blocks.

In another example, a concatenation block can relate to one or more component pre-transformed polar coding blocks.

In yet another example, a concatenation block can relate to one or more component interleaving blocks.

Examples of concatenation blocks are shown in FIGS. 4A-4F.

A concatenation operation can combine multiple input sequences to an output sequence.

In one example, a concatenation comprises obtaining, by the first node, H concatenation input bit sequences x⁽⁰⁾, x⁽¹⁾, . . . , x^{(H-1)}; and determining, by the first node, an output bit sequence e=[e₀, e₁, . . . , e_{E-1}] of length E as e=[x⁽⁰⁾, x⁽¹⁾, . . . , x^{(H-1)}]=[x₀⁽⁰⁾, x₁⁽⁰⁾, . . . , x_{N}_{₀}₋₁⁽⁰⁾, x₀⁽¹⁾, x₁⁽¹⁾, . . . , x_{N}_{₁}₋₁⁽¹⁾, . . . x₀^{(H-1)}, x₁^{(H-1)}, . . . , x_{N}_{_{H−1}}₋₁^{(H-1)}].

Here, E is the length of the output.

For h=0, 1, . . . , H−1, the h-th concatenation input bit sequence x^{(h)}=[x₀^{(h)}, x₁^{(h)}, . . . , x_{N}_{ₕ}₋₁^{(h)}x^{(h)}] is of length Nₕ; with Nₕ as the h-th component polar matrix size.

The output length is equal to the summation of the length of H concatenation input bit sequences x⁽⁰⁾, x⁽¹⁾, . . . , x^{(H-1)}, i.e., E=N₀+N₁+ . . . +N_{H-1}.

In some embodiments, a concatenation input bit sequence x^{(h)} is a component polar coding output bit sequence, as shown in examples in FIGS. 4A and 4E.

In some embodiments, a concatenation input bit sequence x^{(h)} is a component pre-transformed polar coding output bit sequence, as shown in examples in FIGS. 4B and 4F.

In some embodiments, a concatenation input bit sequence x^{(h)} is a component interleaving output bit sequence, as shown in examples in FIGS. 4C to 4F.

In some embodiments, H-W concatenation input bit sequences are component polar coding output bit sequences and W concatenation input bit sequences are component interleaving output bit sequences, wherein H is the number of component polar matrices and W is the number of component interleaver patterns.

In some embodiments, H-W concatenation input bit sequences are component pre-transformed polar coding output bit sequences and W concatenation input bit sequences are component interleaving output bit sequences, wherein H is the number of component polar matrices and W is the number of component interleaver patterns.

In a first specific example with H=3 and W=2, the 0^{th} and the 1^{st} concatenation input bit sequences are both component interleaving output bit sequences while the 2^{nd} concatenation input bit sequence is a component interleaving output bit sequence.

In a second specific example with H=3 and W=1, the 1^{st} concatenation input bit sequence is a component interleaving output bit sequence while the 0^{th} and the 2^{nd} concatenation input bit sequences are both component pre-transformed polar coding output bit sequences.

### Embodiment 5

This section discloses examples involving interleaving operation.

Embodiment 5 is based on all the above embodiments.

One or more component interleaving blocks can be included in the encoding or decoding systems.

The input of a component interleaving block is based on the input sequence c.

In one example, a component interleaving block can be relate to a component polar coding block. In another example, a component interleaving block can be relate to a component pre-transformed polar coding block.

In some embodiments, as in FIGS. 4C and 4D, the number of component interleaver patterns W is equal to the number of component polar matrices H and for h=0, 1, . . . , H−1, the h-th concatenation input bit sequence x^{(h)} is the h-th component interleaving output bit sequence d′^{(h)}=[d′₀^{(h)}, d′₁^{(h)}, . . . , d′_{N}_{ₕ}₋₁^{(h)}] of length Nₕ, wherein Nₕ is the h-th component polar matrix size.

The output bit sequence e=[e₀, e₁, . . . , e_{E-1}] comprises W=H component interleaving output bit sequences d′⁽⁰⁾, d′⁽¹⁾, . . . , d′^{(H-1)}, wherein, for h=0, 1, . . . , H−1, the h-th component interleaving output bit sequence d′^{(h)}=[d′₀^{(h)}, d′₁^{(h)}, . . . , d′_{N}_{ₕ}₋₁^{(h)}] is of length equal to the h-th component polar matrix size Nₕ.

In some embodiments, the output bit sequence e=[e₀, e₁, . . . , e_{E-1}] is a concatenation of H component interleaving output bit sequences d′⁽⁰⁾, d′⁽¹⁾, . . . , d′^{(H-1)} as follows:

$$[ {e}_{0} , {e}_{1} , {e}_{2} , ... , {e}_{E - 1} ] = [ {d}^{′ ( 0 )} , {d}^{′ ( 1 )} , ... , {d}^{′ ( H - 1 )} ] = [ {d}_{0}^{′ ( 0 )} , {d}_{1}^{′ ( 0 )} , … , \\ {d}_{{N}_{0} - 1}^{′ ( 0 )} , {d}_{0}^{′ ( 1 )} , {d}_{1}^{′ ( 1 )} , … , {d}_{{N}_{1} - 1}^{′ ( 1 )} , … , {d}_{0}^{′ ( H - 1 )} , {d}_{1}^{′ ( H - 1 )} , … , {d}_{{N}_{H - 1} - 1}^{′ ( H - 1 )} ]$$

In another example, a component interleaving block can be related to a concatenation block.

In some embodiments, the output bit sequence e=[e₀, e₁, . . . , e_{E-1}] is a concatenation of H component interleaving output bit sequences d′⁽⁰⁾, d′⁽¹⁾, . . . , d′^{(H-1)} as follows:

```
i = 0;
For h = 0 to H-1
  For k = 0 to Nₕ-1
    eᵢ = d′ₖ^{(h)};
    i = i + 1;
  End for
End for
```

FIGS. 4C and 4D give two specific examples for the output bit sequence e being a concatenation of H component output bit sequences d′⁽⁰⁾, d′⁽¹⁾, . . . , d′^{(H-1)}.

### Embodiment 6

This section discloses example systems comprising component interleaving.

Embodiment 6 is based on the above embodiments.

In some embodiments, for h=0, 1, . . . , W−1, the h-th component interleaving output bit sequence d′^{(h)} is an output bit sequence of an h-th component interleaving, wherein, the h-th component interleaving is determined by the h-th component interleaver pattern J^{(h)}=[J₀^{(h)}, J₁^{(h)}, . . . , J_{N}_{ₕ}₋₁^{(h)}] of length Nₕ, wherein Nₕ is the h-th component polar matrix size. In some embodiments, the h-th component interleaver pattern J^{(h)} is determined using the method in Example 1 with a polar matrix size N=Nₕ, wherein Nₕ is the h-th component polar matrix size. In some embodiments, the h-th component interleaver pattern J^{(h)} is determined using the method in Example 2 with a polar matrix size N=Nₕ, wherein Nₕ is the h-th component polar matrix size.

A component interleaving determined by a component interleaver pattern J=[J₀, J₁, . . . , J_{N-2}, J_{N-1}] of length N comprises

obtaining, by the first node, a component interleaving input bit sequence d=[d₀, d₁, . . . , d_{N-1}] of length N; and

determining, by the first node, a component interleaving output bit sequence d′=[d′₀, d′₁, . . . , d′_{N-1}] of length N as

$${{d}^{′}}_{i} = {d}_{{J}_{i}} , i = 0 , 1 , 2 , ... , N - 2 , N - 1 ,$$

i.e., the i-th bit of the interleaving output bit sequence d′ is equal to the Jᵢ-th bit of the interleaving input bit sequence d=[d₀, d₁, . . . , d_{N-1}], wherein, the component interleaver pattern J can be any permutation of the integer sequence [0, 1, 2, . . . , N−2, N−1].

Example 1: A first specific example of a component interleaver pattern J=[J₀, J₁, . . . , J_{N-2}, J_{N-1}] is determined as by a polar matrix size N and a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N-1
  j = floor(32i/N);
  Jᵢ = πⱼ×(N/32) + mod(i, N/32);
End for
```

Example 2: A second specific example of an interleaver pattern J=[J₀, J₁, . . . , J_{N-2}, J_{N-1}] is that the relationship between the index i and the i-th element Jᵢ in the interleaver pattern J satisfies the following quadratic form:

$${J}_{i} = mod ( {f}_{1} \cdot i + {f}_{2} \cdot {i}^{2} , N ) ,$$

where some specific examples of parameters f₁ and f₂ depending on a polar matrix size N are summarized in TABLE 1.

TABLE 1
Interleaver parameters for Example 2

| N | f₁ | f₂ |
|---|---|---|
| 64 | 7 | 16 |
| 128 | 15 | 32 |
| 256 | 15 | 32 |
| 512 | 31 | 64 |
| 1024 | 31 | 64 |
| 2048 | 31 | 64 |
| 4096 | 31 | 64 |

Example 3: A third specific example of a component interleaver pattern J=[J₀, J₁, . . . , J_{N-2}, J_{N-1}] with N=8 is J=[J₀, J₁, J₂, J₃, J₄, J₅, J₆, J₇]=[5, 4, 7, 1, 6, 0, 2, 3].

In some embodiments, for some h being less than H, the following case is equivalent to no component interleaving corresponding to the h-th component polar matrix G^{(N}^{ₕ}⁾:

For any i being non-negative integer smaller than Nₕ, the i-th element Jᵢ^{(h)} of the h-th component interleaver pattern J^{(h)} is equal to i, i.e., J^{(h)}=[J₀^{(h)}, J₁^{(h)}, . . . , c_{N}_{ₕ}₋₁^{(h)}]=[0, 1, . . . , Nₕ−1],

wherein, in another words, in such a case, the number of component interleaver patterns is regarded to be smaller than the number of component polar matrices.

### Embodiment 7

This section discloses examples involving using a component interleaving input bit sequence as a component polar coding output bit sequence.

Embodiment 7 is based on Embodiment 6.

In some embodiments, an input of a component interleaving depends on an output of a component polar coding. In other words, an output of a component polar coding can be an input to a component interleaving.

In some embodiments, as in FIGS. 4C and 4E, a component interleaving input bit sequence d of length N is a component polar coding output bit sequence of length N, wherein N is a component polar matrix size.

In some embodiments, for h=0, 1, . . . , H−1, the h-th component interleaving input bit sequence corresponding to the h-th component interleaving output bit sequence d′^{(h)} is the h-th component polar coding output bit sequence of length Nₕ, wherein Nₕ is the h-th component polar matrix size and a specific example is given in FIG. 4C.

In some embodiments, for h=0, 1, . . . , W−1, the h-th component interleaving input bit sequence corresponding to the h-th component interleaving output bit sequence d′^{(h)} is the h-th component polar coding output bit sequence of length Nₕ, wherein Nₕ is the h-th component polar matrix size; W is the number of component interleaving; a specific example is given in FIG. 4E.

### Embodiment 8

This section discloses examples of output bit sequence comprises component polar coding output bit sequences.

Embodiment 8 is based on the above embodiments.

In some embodiments, as in FIG. 4A, for h=0, 1, . . . , H−1, the h-th concatenation input bit sequence x^{(h)} is the h-th component polar coding output bit sequence d^{(h)}=[d₀^{(h)}, d₁^{(h)}, . . . , d_{N}_{ₕ}₋₁^{(h)}] of length Nₕ, wherein Nₕ is the h-th component polar matrix size. The output bit sequence e=[e₀, e₁, . . . , e_{E-1}] comprises H component polar coding output bit sequences d⁽⁰⁾, d⁽¹⁾, . . . , d^{(H-1)}, wherein, for h=0, 1, . . . , H−1, the h-th component polar coding output bit sequence d^{(h)}=[d₀^{(h)}, d₁^{(h)}, . . . , d_{N}_{ₕ}₋₁^{(h)}] is of length equal to the h-th component polar matrix size Nₕ.

In some embodiments, the output bit sequence e=[e₀, e₁, . . . , e_{E-1}] is a concatenation of H component polar coding output bit sequences d⁽⁰⁾, d⁽¹⁾, . . . , d^{(H-1)} as follows:

$$[ {e}_{0} , {e}_{1} , {e}_{2} , ... , {e}_{E - 1} ] = [ {d}^{( 0 )} , {d}^{( 1 )} , ... , {d}^{( H - 1 )} ] = [ {d}_{0}^{( 0 )} , {d}_{1}^{( 0 )} , … , \\ {d}_{{N}_{0} - 1}^{( 0 )} , {d}_{0}^{( 1 )} , {d}_{1}^{( 1 )} , … , {d}_{{N}_{1} - 1}^{( 1 )} , … , {d}_{0}^{( H - 1 )} , {d}_{1}^{( H - 1 )} , … , {d}_{{N}_{H - 1} - 1}^{( H - 1 )} ] .$$

In some embodiments, the output bit sequence e=[e₀, e₁, . . . , e_{E-1}] is a concatenation of H component polar coding output bit sequences d⁽⁰⁾, d⁽¹⁾, . . . , d^{(H-1)} as follows:

```
i = 0;
For h = 0 to H-1
  For k = 0 to Nₕ-1
    eᵢ = dₖ^{(h)};
  i = i + 1;
  End for
End for
```

FIG. 4A gives a specific example for the output bit sequence e being a concatenation of H component polar coding output bit sequences d⁽⁰⁾, d⁽¹⁾, . . . , d^{(H-1)}.

### Embodiment 9

This section introduces examples involving a component polar coding block.

Embodiment 9 is based on the above embodiments.

In some examples, the input of a polar coding block is based on the input sequence c.

In some examples, a polar coding block is related to a repetition block.

In some examples, a polar coding block is related to a concatenation block.

In some embodiments, for h=0, 1, . . . , H−1, the h-th component polar coding output bit sequence d^{(h)}=[d₀^{(h)}, d₁^{(h)}, . . . , d_{N}_{ₕ}₋₁^{(h)}] of length Nₕ is output of an h-th component polar coding, wherein, the h-th component polar coding is corresponding to the h-th component polar matrix G^{(N}^{ᵣ}⁾; wherein, the h-th component polar coding determines the h-th component polar coding output bit sequence d^{(h)}=[d₀^{(h)}, d₁^{(h)}, . . . , d_{N}_{ₕ}₋₁^{(h)}] by the h-th component data bit index set Q^{(h)} of size Kₕ and the h-th component polar matrix G^{(N}^{ₕ}⁾ of size Nₕ, wherein Kₕ is the h-th component repetition length and Nₕ is the h-th component polar matrix size.

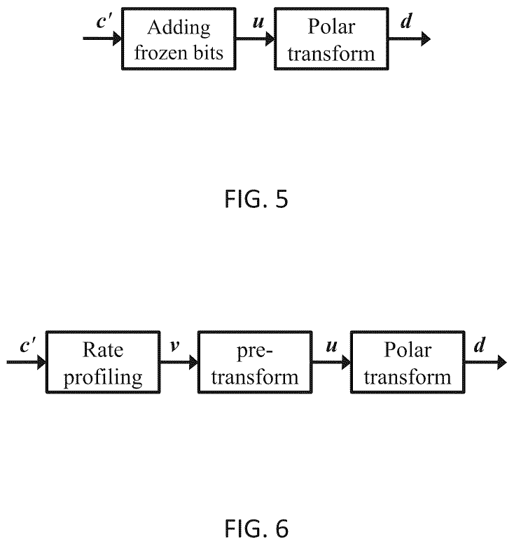

As shown FIG. 5, a component polar coding comprises obtaining, by the first node, a component polar coding input bit sequence c=[c′₀, c′₁, . . . , c′_{K′-1}] of length K′; determining, by the first node, an adding-frozen-bits output bit sequence u=[u₀, u₁, . . . , u_{N-1}] by an adding-frozen-bits operation using a component data bit index set Q′={Q′₀, Q′₁, . . . , Q′_{K′-1}} of size K′; and determining, by the first node, a component polar coding output bit sequence d=[d₀, d₁, . . . , d_{N-1}] of length N by a polar transform using a component polar matrix G^{(N)} of size N as d=u·G^{(N)}.

Here, the polar transform is a vector-matrix multiplication of the adding-frozen-bits output bit sequence u=[u₀, u₁, . . . , u_{N-1}] and the component polar matrix G^{(N)} over GF(2) to obtain the component polar coding output bit sequence d, i.e., d=u·G^{(N)}; K′ is the component repetition length; K′ is a non-negative integer smaller than N; N is the polar matrix size of the component polar matrix G^{(N)}.

### Description of Adding-Frozen-Bits Operation

The adding-frozen-bits operation determining an adding-frozen-bits output bit sequence u=[u₀, u₁, . . . , u_{N-1}] comprises obtaining, by the first node, a component polar coding input bit sequence c′=[c′₀^{(h)}, c′₁^{(h)}, . . . , c′_{K′}_{ₕ}₋₁^{(h)}]; determining, by the first node, an adding-frozen-bits output bit sequence u=[u₀, u₁, . . . , u_{N-1}] by an adding-frozen-bits operation using a component data bit index set Q′={Q′₀, Q′₁, . . . , Q′_{K′-1}} of size K′.

Here, K′ can be the component repetition length; N is the polar matrix size of the component polar matrix G^{(N)}; a specific example is given in FIG. 5.

### Description of Component Data Bit Index Set Q′

In some embodiments, the component data bit index set Q′ is a subset of a fourth-type integer set Z_{N}={0, 1, 2, . . . , N−2, N−1}, wherein, the fourth-type integer set Z_{N}={0, 1, 2, . . . , N−2, N−1} comprises and only comprises all non-negative integers smaller than N. The component data bit index set Q′={Q′₀, Q′₁, . . . , Q′_{K′-1}} has K′ non-negative elements Q′₀, Q′₁, . . . , Q′_{K-2}, Q′_{K-1}, i.e., the component data bit index set Q′ is of size K′.

In some embodiments, for k=0, 1, . . . , K′−2, the element Q′ₖ in the component data bit index set Q′ is smaller than Q′ₖ₊₁, i.e., the component data bit index set Q′ is sorted in ascending order according to index values with Q′₀<Q′₁< . . . <Q′_{K-2}<Q′_{K′-1}. In some embodiments, for k=0, 1, . . . , K′−2, the reliability of the Q′ₖ-th polarized sub-channel (denoted as W(Q′ₖ)) is smaller than the reliability of the Q′ₖ₊₁-th polarized sub-channel (denoted as W(Q′ₖ₊₁)), i.e., the component data bit index set Q′ is sorted in ascending order according to the polarized sub-channel reliability with W(Q′₀)<W(Q′₁)< . . . <W(Q_{K′-2})<W(Q′_{K-1}). In some embodiments, for k=0, 1, . . . , K′−2, the element Q′ₖ in the component data bit index set Q′ is greater than Q′ₖ₊₁, i.e., the component data bit index set Q′ is sorted in descending order according to index values with Q′₀>Q′₁> . . . >Q′_{K-2}>Q′_{K′-1}. In some embodiments, for k=0, 1, . . . , K′−2, the reliability of the Q′ₖ-th polarized sub-channel (denoted as W(Q′ₖ)) is greater than the reliability of the Q′ₖ₊₁-th polarized sub-channel (denoted as W(Q′ₖ₊₁)), i.e., the component data bit index set Q′ is sorted in descending order according to the polarized sub-channel reliability with W(Q′₀)>W(Q′₁)> . . . >W(Q′_{K′-2})>W(Q′_{K′-1}).

In a first specific example with N=8 and K′=4, a component data bit index set is Q′={Q′₀, Q′₁, Q′₂, Q′₃}={3, 5, 6, 7}. In a second specific example with N=32 and K′=25, a component data bit index set is Q′={Q′₀, Q′₁, Q′₂, Q′₃, Q′₄, Q′₅, Q′₆, Q′₇, Q′₈, Q′₉, Q′₁₀, Q′₁₁, Q′₁₂, Q′₁₃, Q′₁₄, Q′₁₅, Q′₁₆, Q′₁₇, Q′₁₈, Q′₁₉, Q′₂₀, Q′₂₁, Q′₂₂, Q′₂₃, Q′₂₄}={5, 9, 6, 17, 10, 18, 12, 20, 24, 7, 11, 19, 13, 14, 21, 26, 25, 22, 28, 15, 23, 31, 27, 29, 30} with polarized sub-channel reliability with W(Q′₀)<W(Q′₁)<W(Q′₂)<W(Q′₃)<W(Q′₄)<W(Q′₅)<W(Q′₆)<W(Q′₇)<W(Q′₈)<W(Q′₉)<W(Q′₁₀)<W(Q′₁₁)<W(Q′₁₂)<W(Q′₁₃)<W(Q′₁₄)<W(Q′₁₅)<W(Q′₁₆)<W(Q′₁₇)<W(Q′₁₈)<W(Q′₁₉)<W(Q′₂₀)<W(Q′₂₁)<W(Q′₂₂)<W(Q′₂₃)<W(Q′₂₄). In a third specific example with N=8 and K′=4, a component data bit index set is Q′={Q′₀, Q′₁, Q′₂, Q′₃}={7, 6, 5, 3}.

In some embodiments, the adding-frozen-bits operation determines the adding-frozen-bits output bit sequence u=[u₀, u₁, . . . , u_{N-1}] corresponding to the adding-frozen-bits input bit sequence c′=[c′₀, c′₁, . . . , c′_{K′-1}] according to the component data bit index set Q′ is as follows.

```
For each index i = 0, 1, ..., N-1,
    if the index i belongs to the component data bit index set
  Q′, the i-th bit uᵢ in the adding-frozen-bits output bit sequence
  u is set to a bit in the adding-frozen-bits input bit sequence c′;
    if the index i does not belongs to the data bit index set Q′,
  the i-th bit uᵢ in the adding-frozen-bits output bit sequence
  u is set to a bit zero (“0”);
End for
```

wherein, a specific example pseudo-code for the adding-frozen-bits operation is as follows.

```
k = 0;
For i = 0 to N − 1
  If i ∈ Q′
    uᵢ = c′ₖ;
    k = k + 1;
  Else
    uᵢ = 0;
  End if
End for
```

In some embodiments, for an index i belonging to the component data bit index set Q′, the bit uᵢ in the adding-frozen-bits output bit sequence u is set to a bit in the adding-frozen-bits input bit sequence c′.

A first specific example with N=8, K′=3 and a component data bit index set Q′={5, 6, 7}, an adding-frozen-bits input bit sequence c′=[c′₀, c′₁, c′₂], the bits u₅, u₆, u₇ with indices belonging to the component data bit index set Q′={5, 6, 7} in an adding-frozen-bits output bit sequence u=[u₀, u₁, u₂, u₃, u₄, u₅, u₆, u₇] is set as u₅=c′₀, u₆=c′₁, and u₇=c′₂.

A second specific example with N=16, K′=6 and a component data bit index set Q′={12, 7, 11, 13, 14, 15}, an adding-frozen-bits input bit sequence c′=[c′₀, c′₁, c′₂, c′₃, c′₄, c′₅], the bits u₁₂, u₇, u₁₁, u₁₃, u₁₄, u₁₅ with indices belonging to the data bit index set Q′={12, 7, 11, 13, 14, 15} in an adding-frozen-bits output bit sequence u=[u₀, u₁, u₂, u₃, u₄, u₅, u₆, u₇, u₈, u₉, u₁₀, u₁₁, u₁₂, u₁₃, u₁₄, u₁₅] is set as u₁₂=c′₀, u₇=c′₁, u₁₁=x′₂, u₁₃=c₃, u₁₄=c′₄, and u₁₅=c′₅. A third specific example is given as

```
k = 0;
For i = 0 to N-1
  If i ∈ Q′
    uᵢ = c′ₖ;
    k = k + 1;
  Else
    uᵢ = 0;
  End if
End for
```

In some embodiments, for an index i not belonging to the component data bit index set Q′, the bit uᵢ in the adding-frozen-bits output bit sequence u is equal to 0.

A first specific example with N=8, K′=3 and Q′={5, 6, 7}, the bits u₀, u₁, u₂, u₃, u₄ with indices not belonging to the component data bit index set Q′={5, 6, 7} in an adding-frozen-bits output bit sequence u=[u₀, u₁, u₂, u₃, u₄, u₅, u₆, u₇] is set as u₀=0, u₁=0, u₂=0, u₃=0, and u₄=0.

A second specific example with N=16, K′=6 and Q′={7, 11, 12, 13, 14, 15}, the bits u₀, u₁, u₂, u₃, u₄, u₅, u₆, u₈, u₉, u₁₀ with indices not belonging to the component data bit index set Q′={7, 11, 12, 13, 14, 15} in an adding-frozen-bits output bit sequence u=[u₀, u₁, u₂, u₃, u₄, u₅, u₆, u₇, u₈, u₉, u₁₀, u₁₁, u₁₂, u₁₃, u₁₄, u₁₅] is set as u₀=0, u₁=0, u₂=0, u₃=0, u₄=0, u₅=0, u₆=0, u₈=0, u₉=0, and u₁₀=0. A third specific example is given as

```
k = 0;
For i = 0 to N-1
  If i ∈ Q′
    uᵢ = c′ₖ;
    k = k + 1;
  Else
    uᵢ = 0;
  End if
End for
```

In some embodiments, the adding-frozen-bits output bit sequence u is the multiplexing of the adding-frozen-bits input bit sequence c′ and an all-zero sequence of length N−K′, wherein N is the polar matrix size and K′ is the adding-frozen-bits input bit sequence length.

A first specific example with N=8 and K′=3 is an adding-frozen-bits input bit sequence c′=[c′₀, c′₁, c′₂] and an all-zero sequence of length N−K′=8−3=5, then an adding-frozen-bits output bit sequence u=[u₀, u₁, u₂, u₃, u₄, u₅, u₆, u₇]=[0, 0, 0, 0, 0, c₀, c₁, c₂].

A second specific example with N=16, K′=6, an adding-frozen-bits input bit sequence c′=[c′₀, c′₁, c′₂, c′₃, c′₄, c′₅] and an all-zero sequence of length N−K′=16−4=12, then an adding-frozen-bits output bit sequence u=[u₀, u₁, u₂, u₃, u₄, u₅, u₆, u₇, u₈, u₉, u₁₀, u₁₁, u₁₂, u₁₃, u₁₄, u₁₅]=[0, 0, 0, 0, 0, 0, 0, 0, 0, 0, c₀, 0, c₁, c₂, c₃] is determined.

### Embodiment 10

This section discloses examples involving using a component interleaving input bit sequence as a component pre-transformed polar coding output bit sequence.

Embodiment 10 is based on the above related embodiments.

In some embodiments, an input of a component interleaving depends on the output of a component pre-transform polar coding. In other words, an output of a component pre-transform polar coding can be an input to a component interleaving.

In one example, a component interleaving input bit sequence d of length N is a component pre-transformed polar coding output bit sequence of length N, wherein N is a component polar matrix size.

In some embodiments, for h=0, 1, . . . , H−1, the h-th component interleaving input bit sequence corresponding to the h-th component interleaving output bit sequence d′^{(h)} is the h-th component pre-transformed polar coding output bit sequence d^{(h)}=[d₀^{(h)}, d₁^{(h)}, . . . , d_{N}_{ₕ}₋₁^{(h)}] of length Nₕ, wherein Nₕ is the h-th component polar matrix size and a specific example is given in FIG. 4D.

In some embodiments, for h=0, 1, . . . , W−1, the h-th component interleaving input bit sequence corresponding to the h-th component interleaving output bit sequence d′^{(h)} is the h-th component pre-transformed polar coding output bit sequence d^{(h)}=[d₀^{(h)}, d₁^{(h)}, . . . , d_{N}_{ₕ}₋₁^{(h)}] of length Nₕ, wherein Nₕ is the h-th component polar matrix size; W is the number of component interleaving; a specific example is given in FIG. 4F.

### Embodiment 11

This section discloses examples of output bit sequence comprises component pre-transformed polar coding output bit sequences.

Embodiment 11 is based on the above related embodiments.

In some embodiments, as in FIG. 4B, for h=0, 1, . . . , H−1, the h-th concatenation input bit sequence x^{(h)} is the h-th component pre-transformed polar coding output bit sequence d^{(h)}=[d₀^{(h)}, d₁^{(h)}, . . . , d_{N}_{ₕ}₋₁^{(h)}] of length Nₕ, wherein Nₕ is the h-th component polar matrix size. The output bit sequence e=[e₀, e₁, . . . , e_{E-1}] comprises H component pre-transformed polar coding output bit sequences d⁽⁰⁾, d⁽¹⁾, . . . , d^{(H-1)}, wherein, for h=0, 1, . . . , H−1, the h-th component pre-transformed polar coding output bit sequence d^{(h)}=[d₀^{(h)}, d₁^{(h)}, . . . , d_{N}_{ₕ}₋₁^{(h)}] is of length equal to the h-th component polar matrix size Nₕ.

In some embodiments, the output bit sequence e=[e₀, e₁, . . . , e_{E-1}] is a concatenation of H component pre-transformed polar coding output bit sequences d⁽⁰⁾, d⁽¹⁾, . . . , d^{(H-1)} as follows:

$$[ {e}_{0} , {e}_{1} , {e}_{2} , ... , {e}_{E - 1} ] = [ {d}^{( 0 )} , {d}^{( 1 )} , ... , {d}^{( H - 1 )} ] = [ {d}_{0}^{( 0 )} , {d}_{1}^{( 0 )} , … , \\ {d}_{{N}_{0} - 1}^{( 0 )} , {d}_{0}^{( 1 )} , {d}_{1}^{( 1 )} , … , {d}_{{N}_{1} - 1}^{( 1 )} , … , {d}_{0}^{( H - 1 )} , {d}_{1}^{( H - 1 )} , … , {d}_{{N}_{H - 1} - 1}^{( H - 1 )} ] .$$

In some embodiments, the output bit sequence e=[e₀, e₁, . . . , e_{E-1}] is a concatenation of H component pre-transformed polar coding output bit sequences d⁽⁰⁾, d⁽¹⁾, . . . , d^{(H-1)} as follows:

```
i = 0;
For h = 0 to H-1
  For k = 0 to Nₕ-1
    eᵢ = dₖ^{(h)};
    i = i + 1;
  End for
End for
```

FIG. 4B gives a specific example for the output bit sequence e being a concatenation of H component pre-transformed polar coding output bit sequences d⁽⁰⁾, d⁽¹⁾, . . . , d^{(H-1)}.

### Embodiment 12

This section discloses examples involving a component pre-transformed polar coding.

Embodiment 12 is based on the above embodiments.

In some embodiments, for h=0, 1, . . . , H−1, the h-th component pre-transformed polar coding output bit sequence d^{(h)}=[d₀^{(h)}, d₁^{(h)}, . . . , d_{N}_{ₕ}₋₁^{(h)}] of length Nₕ is output of an h-th component pre-transformed polar coding, wherein, the h-th component pre-transformed polar coding is corresponding to the h-th component polar matrix G^{(N}^{ₕ}⁾; the h-th component pre-transformed polar coding determines the h-th component pre-transformed polar coding output bit sequence d^{(h)}=[d₀^{(h)}, d₁^{(h)}, . . . , d_{N}_{ₕ}₋₁^{(h)}] by at least one of the following:
1) the h-th component data bit index set Q^{(h)} of size Kₕ,
2) the h-th component generator polynomial g^{(h)}(D) over GF(2),
3) the h-th component recursive feedback polynomial q^{(h)}(D) over GF(2), or
4) the h-th component polar matrix G^{(N}^{ₕ}⁾ of size Nₕ.

Here, Kₕ is the h-th component repetition length and Nₕ is the h-th component polar matrix size.

As shown FIG. 6, a component pre-transformed polar coding comprises obtaining, by the first node, a component pre-transformed polar coding input bit sequence c′=[c′₀, c′₁, . . . , c′_{K′-1}] of length K′; and determining, by the first node, a rate profiling output bit sequence v=[v₀, v₁, . . . , v_{N-1}] by a rate profiling using a component data bit index set Q′={Q′₀, Q′₁, . . . , Q′_{K′-1}} of size K′; and determining, by the first node, a pre-transform output bit sequence u=[u₀, u₁, . . . , u_{N-1}] by a pre-transform using at least one of the following: a component generator polynomial g(D)=g₀+g₁·D+ . . . +gₘ·D^{m} over GF(2), a component recursive feedback polynomial q(D)=q₀+q₁·D+ . . . +qₘ·D^{m}; and determining, by the first node, a component pre-transformed polar coding output bit sequence d=[d₀, d₁, . . . , d_{N-1}] of length N by a polar transform using a component polar matrix G^{(N)} of size N as d=u·G^{(N)}.

Here, the polar transform is a vector-matrix multiplication of the pre-transform output bit sequence u=[u₀, u₁, . . . , u_{N-1}] and the component polar matrix G^{(N)} over GF(2) to obtain the component polar coding output bit sequence d, i.e., d=u·G^{(N)}; K′ is the component repetition length; K′ is a non-negative integer smaller than N; N is the polar matrix size of the component polar matrix G^{(N)}.

### Description of Rate Profiling

The rate profiling is an operation exactly the same as the adding-frozen-bits operation, wherein the component polar coding input bit sequence is the component pre-transformed polar coding input bit sequence c′=[c′₀, c′₁, . . . , c′_{K′-1}] of length K′; the adding-frozen-bits output bit sequence is the rate profiling output bit sequence v=[v₀, v₁, . . . , v_{N-1}].

### Description of Pre-Transform

The pre-transform in the component pre-transformed polar coding comprises obtaining, by the first node, a pre-transform input bit sequence of length N, and determining, by the first node, the pre-transform output bit sequence u=[u₀, u₁, . . . , u_{N-1}] by using at least one of the following: a component generator polynomial g(D)=g₀+g₁·D+ . . . +gₘ·Dₘ over GF(2), a component recursive feedback polynomial q(D)=q₀+q₁·D+ . . . +qₘ·D^{m}.

Here, N is the component polar matrix size; m is a component memory length; the pre-transform input bit sequence is the rate profiling output bit sequence v=[v₀, v₁, . . . , v_{N-1}] of length N; wherein a specific example is given in FIG. 6.

Pre-Transform Using a Generator Polynomial g(D) or a Generator Bit Sequence g

In some embodiments, the pre-transform determines the pre-transform output bit sequence u corresponding to the pre-transform input bit sequence v=[v₀, v₁, . . . , v_{N-1}] of length N according to a generator polynomial g(D)=g₀+g₁·D+g₂·D+ . . . +gₘ₋₁·D+gₘ·D (or equivalently a generator bit sequence g=[g₀, g₁, g₂, . . . , gₘ₋₁, gₘ]), wherein m is called a memory length of the generator polynomial g(D) (or the generator bit sequence g).

The generator polynomial g(D)=g₀+g₁·D+ . . . +gₘ₋₁·D^{m-1}+gₘ·D^{m} can be any binary polynomial over GF(2), wherein m is the polynomial degree or the memory length. In a specific example with a memory length m=6, a generator polynomial is g(D)=g₀+g₁·D+g₂·D²+g₃·D³+g₄·D⁴+g₅·D⁵+g₆·D⁶=1+0·D+1·D²+1·D³+0·D⁴+1·D⁵+1·D⁶=1+D²+D³+D⁵+D⁶. In another specific example with a memory length m=3, a generator polynomial is g(D)=g₀+g₁·D+g₂·D²+g₃·D³=1+1·D+0·D²+1·D³=1+D+D³. The generator bit sequence g=[g₀, g₁, . . . , gₘ] can be any binary sequence of length m+1, wherein m is called the memory length. In a specific example with a memory length m=6, a generator bit sequence is g=[g₀, g₁, g₂, g₃, g₄, g₅, g₆]=[1, 0, 1, 1, 0, 1, 1]. In another specific example with a memory length m=3, a generator bit sequence is g=[g₀, g₁, g₂, g₃]=[1, 1, 0, 1].

FIG. 3 shows a specific example diagram of a pre-transform using a generator polynomial g(D)=g₀+g₁·D+ . . . +gₘ₋₁·D^{m-1}+gₘ·D^{m} (or a generator bit sequence g=[g₀, g₁, . . . , gₘ]) of a memory length m, wherein a bit uᵢ with an index i in a pre-transform output bit sequence u is determined by m+1 bit vᵢ, vᵢ₋₁, vᵢ₋₂, . . . , vᵢ₋ₘ with consecutive indices i, i−1, i−2, . . . , i−m in a pre-transform input bit sequence v and the generator polynomial g(D)=g₀+g₁·D+ . . . +gₘ₋₁·D^{m-1}+gₘ·D^{m} (or the generator bit sequence g=[g₀, g₁, . . . , gₘ]) as

$${u}_{i} = {\sum }_{k = 0}^{m} {g}_{k} \cdot {v}_{i - k} ,$$

wherein the summation and the multiplication are over GF(2); the bit vᵢ₋ₖ=0 for i<k; gₖ is a coefficient of the term with degree k in the generator polynomial g(D)=g₀+g₁·D+ . . . +gₘ₋₁·D^{m-1}+gₘ·D^{m} (or equivalently a bit with an index k in a generator bit sequence g=[g₀, g₁, . . . , gₘ]) over GF(2). A specific pseudo code is as follows.

```
For i = 0 to N-1
  k = 0;
  uᵢ = 0;
  While k ≤ m && k ≤ i
    uᵢ = mod(uᵢ + gₖ · vᵢ₋ₖ, 2);
    k = k + 1;
  End while
End for
```

Pre-Transform Using a Recursive Feedback Polynomial q(D) or a Recursive Feedback Sequence a

In some embodiments, the pre-transform determines the pre-transform output bit sequence u corresponding to the pre-transform input bit sequence v according to a recursive feedback polynomial q(D)=q₀+q₁·D+q₂·D+ . . . +qₘ₋₁·D+qₘ·D (or equivalently a recursive feedback bit sequence q=[q₀, q₁, q₂, . . . , qₘ₋₁, qₘ]), wherein m is called a memory length of the recursive feedback polynomial q(D) (or the recursive feedback bit sequence q).

The recursive feedback polynomial q(D)=q₀+q₁·D+ . . . +qₘ₋₁·D^{m-1}+qₘ·D^{m} is a binary polynomial with the zero-degree coefficient q₀ being 1 and other coefficients q₁, . . . , qₘ being any binary values over GF(2), wherein m is a memory length.

In a specific example with a memory length m=6, a recursive feedback polynomial is q(D)=q₀+q₁·D+q₂·D²+q₃·D³+q₄·D⁴+q₅·D⁵+q₆·D⁶=1+0·D+1·D²+0·D³+1·D⁴+1·D⁵+1·D⁶=1+D²+D⁴+D⁵+D⁶. In another specific example with a memory length m=3, a recursive feedback polynomial is q(D)=q₀+q₁·D+q₂·D²+q₃·D³=1+0·D+1·D²+1·D³=1+D²+D³. The recursive feedback bit sequence q=[q₀, q₁, . . . , qₘ] is a binary sequence of length m+1 with [q₁, . . . , qₘ] being any binary sequence of length m and q₀=1, wherein m is the memory length. In a specific example with a memory length m=3, a recursive feedback bit sequence is q=[q₀, q₁, q₂, q₃, q₄, q₅, q₆]=[1, 0, 1, 0, 1, 1, 1]. In another specific example with a memory length m=3, a recursive feedback bit sequence is q=[q₀, q₁, q₂, q₃]=[1, 0, 1, 1].

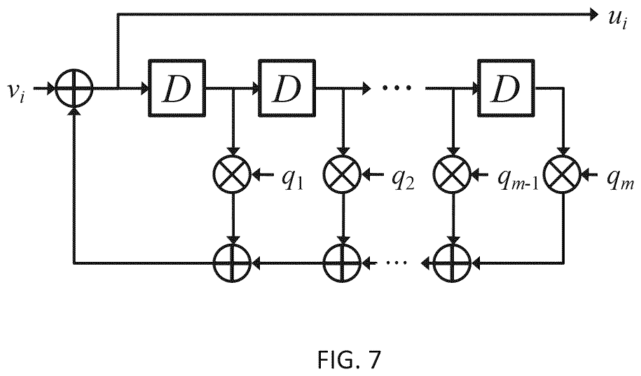

FIG. 7 shows a specific diagram of a pre-transform using a recursive feedback polynomial q(D)=q₀+q₁·D+ . . . +qₘ₋₁·D^{m-1}+qₘ·D^{m} (or equivalently a recursive feedback bit sequence q=[q₀, q₁, q₂, . . . , q^{m-1}, qₘ]) with q₀=1 and a memory length m, wherein a bit uᵢ with an index i in a pre-transform output bit sequence u is determined by the following
1) a bit vᵢ with an index i in a pre-transform input bit sequence v,
2) m previous bits uᵢ₋₁, uᵢ₋₂, . . . , uᵢ₋ₘ with consecutive indices i−1, i−2, . . . , i−m in a pre-transform output bit sequence u, and/or
3) a recursive feedback polynomial q(D)=q₀+q₁·D+ . . . +qₘ₋₁·D^{m-1}+qₘ·D^{m} (or a recursive feedback bit sequence q=[q₀, q₁, . . . , qₘ]) with q₀=1,

Here, a specific example is

$${u}_{i} = {v}_{i} + {\sum }_{k = 1}^{m} {q}_{k} \cdot {u}_{i - k}$$

with the summation and the multiplication being over GF(2); the bit uᵢ₋ₖ=0 for i<k; qₖ is a coefficient of the term with degree k in the recursive feedback polynomial q(D)=q₀+q₁·D+ . . . +qₘ₋₁·D^{m-1}+qₘ·D^{m} (or equivalently a bit with an index k in a recursive feedback bit sequence q=[q₀, q₁, . . . , qₘ]) over GF(2). A specific pseudo code is as follows.

```
For i = 0 to N-1
  k = 1;
  uᵢ = vᵢ,
  While k ≤ m && k ≤ i
    uᵢ = mod(uᵢ + qₖ · uᵢ₋ₖ, 2);
    k = k + 1;
  End while
End for
```

Pre-Transform Using Both a Generator Polynomial g(D) and a Recursive Feedback Polynomial q(D) (or Both a Generator Bit Sequence g and a Recursive Feedback Bit Sequence q)

In some embodiments, the pre-transform determines the pre-transform output bit sequence u corresponding to the pre-transform input bit sequence v according to both a generator polynomial g(D)=g₀+g₁·D+g₂·D+ . . . +gₘ₋₁·D+gₘ·D and a recursive feedback polynomial q(D)=q₀+q₁·D+ . . . +qₘ₋₁·D^{m-1}+qₘ·D^{m} (or equivalently both a generator bit sequence g=[g₀, g₁, g₂, . . . , gₘ₋₁, gₘ] and a recursive feedback bit sequence q=[q₀, q₁, q₂, . . . , qₘ₋₁, qₘ]), wherein m is called a memory length for both the generator polynomial g(D) and the recursive feedback polynomial q(D) (or equivalently both the generator bit sequence g and the recursive feedback bit sequence q).

The generator polynomial g(D)=g₀+g₁·D+ . . . +gₘ₋₁·D^{m-1}+gₘ·D^{m} can be any binary polynomial over GF(2), wherein m is the polynomial degree or the memory length.

In a specific example with a memory length m=6, a generator polynomial is g(D)=g₀+g₁·D+g₂·D²+g₃·D³+g₄·D⁴+g₅·D⁵+g₆·D⁶=1+0·D+1·D²+1·D³+0·D⁴+1·D⁵+1·D⁶=1+D²+D³+D⁵+D⁶. In another specific example with a memory length m=3, a generator polynomial is g(D)=g₀+g₁·D+g₂·D²+g₃·D³=1+1·D+0·D²+1·D³=1+D+D³. The generator bit sequence g=[g₀, g₁, . . . , gₘ] can be any binary sequence of length m+1, wherein m is called the memory length. In a specific example with a memory length m=6, a generator bit sequence is g=[g₀, g₁, g₂, g₃, g₄, g₅, g₆]=[1, 0, 1, 1, 0, 1, 1].

In another specific example with a memory length m=3, a generator bit sequence is g=[g₀, g₁, g₂, g₃]=[1, 1, 0, 1]. The recursive feedback polynomial q(D)=q₀+q₁·D+ . . . +qₘ₋₁·D^{m-1}+qₘ·D^{m} is a binary polynomial with the zero-degree coefficient q₀ being 1 and other coefficients q₁, . . . , qₘ being any binary values over GF(2), wherein m is the memory length. In a specific example with a memory length m=6, a recursive feedback polynomial is q(D)=q₀+q₁·D+q₂·D²+q₃·D³+q₄·D⁴+q₅·D⁵+q₆·D⁶=1+0·D+1·D²+0·D³+1·D⁴+1·D⁵+1·D⁶=1+D²+D⁴+D⁵+D⁶. In another specific example with a memory length m=3, a recursive feedback polynomial is q(D)=q₀+q₁·D+q₂·D²+q₃·D³=1+0·D+1·D²+1·D³=1+D²+D³. The recursive feedback bit sequence q=[q₀, q₁, . . . , qₘ] is a binary sequence of length m+1 with [q₁, . . . , qₘ] being any binary sequence of length m and q₀=1, wherein m is the memory length. In a specific example with a memory length m=3, a recursive feedback bit sequence is q=[q₀, q₁, q₂, q₃, q₄, q₅, q₆]=[1, 0, 1, 0, 1, 1, 1]. In another specific example with a memory length m=3, a recursive feedback bit sequence is q=[q₀, q₁, q₂, q₃]=[1, 0, 1, 1].

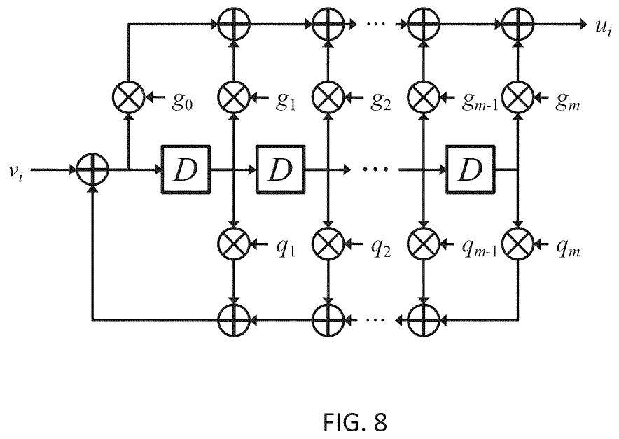

FIG. 8 shows a diagram of a pre-transform using both a generator polynomial g(D)=g₀+g₁·D+ . . . +gₘ₋₁·D^{m-1}+gₘ·D^{m} and a recursive feedback polynomial q(D) (or equivalently both a generator bit sequence g and a recursive feedback bit sequence q).

Here the pre-transform determines a bit uᵢ with an index i in a pre-transform output bit sequence u comprising setting, by the first node, a bit to with an index 0 in a state bit sequence t=[t₀, t₁, t₂, . . . , tₘ] to be a bit vᵢ with an index i of a pre-transform input bit sequence v=[v₀, v₁, v₂, . . . , v_{N-1}], i.e., t₀=vᵢ; and determining, by the first node, a summation bit s by the recursive feedback polynomial q(D)=q₀+q₁·D+ . . . +qₘ·D^{m} (or equivalently the feedback bit sequence q=[q₀, q₁, . . . , qₘ]) over GF(2) and the updated state bit sequence t=[t₀, t₁, t₂ . . . , tₘ₋₁, tₘ] as s=mod(Σⱼ₌₀^{m} qⱼ·tⱼ, 2); setting, by the first node, a bit t₀ with an index 0 in the state bit sequence t=[t₀, t₁, t₂ . . . , tₘ₋₁, tₘ] to the summation bit s, i.e., t₀=s, and determining, by the first node, a bit uᵢ with an index i of a pre-transform output bit sequence u=[u₀, u₁, u₂, . . . , u_{N-1}] by a generator polynomial g(D)=g₀+g₁·D+ . . . +gₘ·D^{m} (or equivalently a generator bit sequence g=[g₀, g₁, . . . , gₘ]) over GF(2) and the updated state bit sequence t=[t₀, t₁, . . . , tₘ₋₁, tₘ] as uᵢ=mod(Σⱼ₌₀^{m}gⱼ·tⱼ, 2) and performing, by the first node, a right shift on the state bit sequence t=[t₀, t₁, . . . , tₘ₋₁, tₘ] with a bit t₀ with index 0 in the state bit sequence t=[t₀, t₁, . . . , tₘ₋₁, tₘ] is set to 0 as follows.

For j = m to 1
tⱼ = tⱼ₋₁;
End for
t₀ = 0;

A specific pseudo code for the above steps is as follows.

```
For j = 0 to m
  tⱼ = 0;
End for
k = 0;
For i = 0 to N-1
    s = 0;
    t₀ = vᵢ;
    For j = 0 to m
      s = mod(s + qⱼ · tⱼ, 2);
    End for
    t₀ = S;
    uᵢ = 0;
    For j = 0 to m
      uᵢ = mod(uᵢ + gⱼ · tⱼ, 2);
    End for
    For j = m to 1
      tⱼ = tⱼ₋₁;
    End for
End for
```

### Embodiment 13

This section discloses examples using repetition output bit sequences as the input bit sequences for component polar coding.

Embodiment 13 is based on the above embodiments.

In some embodiments, for h=0, 1, . . . , H−1, the h-th component polar coding input bit sequence c^{(h)}=[c₀^{(h)}, c₁^{(h)}, . . . , c_{K}_{ₕ}₋₁^{(h)}] of length Kₕ is an h-th component repetition output bit sequence, wherein, the h-th component polar coding input bit sequence is corresponding to the h-th component polar matrix G^{(N}^{ₕ}⁾; Nₕ is the h-th polar matrix size; Kₕ is the h-th component repetition length; the H component repetition output bit sequences c⁽⁰⁾, c⁽¹⁾, . . . , c^{(H-1)} are outputs of a repetition.

### Embodiment 14

This section discloses examples involving use repetition output bit sequences as component pre-transformed polar coding input bit sequences.

Embodiment 14 is based on Embodiment 12.

In some embodiments, for h=0, 1, . . . , H−1, the h-th component pre-transformed polar coding input bit sequence c^{(h)}=[c₀^{(h)}, c₁^{(h)}, . . . , c_{K}_{ₕ}₋₁^{(h)}] of length Kₕ is an h-th component repetition output bit sequence, wherein, the h-th component pre-transformed polar coding input bit sequence is corresponding to the h-th component polar matrix G^{(N}^{ₕ}⁾; Nₕ is the h-th polar matrix size; Kₕ is the h-th component repetition length; the H component repetition output bit sequences c⁽⁰⁾, c⁽¹⁾, . . . , c^{(H-1)} are outputs of a repetition.

### Embodiment 15

This section discloses examples related to a repetition block.

Embodiment 15 is based on the above related embodiments.

In some embodiment, the repetition comprises obtaining, by the first node, an input bit sequence c=[c₀, c₁, . . . , c_{K-1}] of length K; and determining, by the first node, the H component repetition output bit sequences c⁽⁰⁾, c⁽¹⁾, . . . , c^{(H-1)} by at least one of the following: the H component repetition lengths K₀, K₁, . . . , K_{H-1}, the H component repetition index sets R⁽⁰⁾, R⁽¹⁾, . . . , R^{(H-1)}.

Here, for h=0, 1, . . . , H−1, the h-th component repetition output bit sequence c^{(h)}=[c₀^{(h)}, c₁^{(h)}, . . . , c_{K}_{ₕ}₋₁^{(h)}] is of length Kₕ.

In some embodiments, for h=0, 1, . . . , H−1, the repetition determines the h-th component repetition output bit sequence c^{(h)} by setting the k-th bit cₖ^{(h)} in the h-th component repetition output bit sequence c^{(h)} to the bit with an index Rₖ^{(h)} in the input bit sequence c=[c₀, c₁, . . . , c_{K-1}], i.e., cₖ^{(h)}=c_{R}_{ₖ}_{^{(h)}}, wherein a pseudo-code is as follows.

```
For h = 0 to H-1
  For k = 0 to Kₕ-1
  cₖ^{(h)} = c_{R}_{ₖ}^{₍ₕ₎};
  End for
End for
```

In a first specific example with K=6, an input bit sequence c=[c₀, c₁, c₂, c₃, c₄, c₅], H=2 component repetition index sets R⁽⁰⁾={0, 1, 2, 3, 4, 5} with K₀=6 and R⁽¹⁾={0, 1, 2} with K₁=3, the 0th component repetition output bit sequence

$${c}^{( 0 )} = [ {c}_{0}^{( 0 )} , {c}_{1}^{( 0 )} , {c}_{2}^{( 0 )} , {c}_{3}^{( 0 )} , {c}_{4}^{( 0 )} , \\ {c}_{5}^{( 0 )} ] = [ {c}_{{R}_{0}^{( 0 )}} , {c}_{{R}_{1}^{( 0 )}} , {c}_{{R}_{2}^{( 0 )}} , {c}_{{R}_{3}^{( 0 )}} , {c}_{{R}_{4}^{( 0 )}} , {c}_{{R}_{5}^{( 0 )}} ] = [ {c}_{0} , {c}_{1} , {c}_{2} , {c}_{3} , {c}_{4} , {c}_{5} ]$$

and the 1^{st} component repetition output bit sequence c⁽¹⁾=[c₀⁽¹⁾, c₁⁽¹⁾, . . . , c₂⁽¹⁾]=[, c_{R}_{₀}_{⁽¹⁾}, c_{R}_{₁}_{⁽¹⁾}, c_{R}_{₂}_{⁽¹⁾}]=[c₀, c₁, c₂].

In a second specific example with K=6, an input bit sequence c=[c₀, c₁, c₂, c₃, c₄, c₅], H=3 component repetition index sets R⁽⁰⁾={0, 1, 2, 3, 4, 5} with K₀=6, R⁽¹⁾={0, 1, 2} with K₁=3 and R⁽²⁾={4} with K₂=1, the 0th component repetition output bit sequence

$${c}^{( 0 )} = [ {c}_{0}^{( 0 )} , {c}_{1}^{( 0 )} , {c}_{2}^{( 0 )} , {c}_{3}^{( 0 )} , {c}_{4}^{( 0 )} , \\ {c}_{5}^{( 0 )} ] = [ {c}_{{R}_{0}^{( 0 )}} , {c}_{{R}_{1}^{( 0 )}} , {c}_{{R}_{2}^{( 0 )}} , {c}_{{R}_{3}^{( 0 )}} , {c}_{{R}_{4}^{( 0 )}} , {c}_{{R}_{5}^{( 0 )}} ] = [ {c}_{0} , {c}_{1} , {c}_{2} , {c}_{3} , {c}_{4} , {c}_{5} ] ,$$

the 1^{st} component repetition output bit sequence

$${c}^{( 1 )} = [ {c}_{0}^{( 1 )} , {c}_{1}^{( 1 )} , {c}_{2}^{( 1 )} ] = [ {c}_{{R}_{0}^{( 1 )}} , {c}_{{R}_{1}^{( 1 )}} , {c}_{{R}_{2}^{( 1 )}} ] = [ {c}_{0} , {c}_{1} , {c}_{2} ]$$

and the 2^{nd} component repetition output bit sequence

$${c}^{( 2 )} = [ {c}_{0}^{( 2 )} ] = [ {c}_{{R}_{0}^{( 2 )}} ] = [ {c}_{4} ] .$$

In a third specific example with K=6, an input bit sequence c=[c₀, c₁, c₂, c₃, c₄, c₅], H=3 component repetition index sets R⁽⁰⁾={0, 1, 2, 4, 3} with K₀=5, R⁽¹⁾ {0, 5} with K₁=2, and R⁽²⁾={4} with K₂=1, the 0th component repetition output bit sequence

$${c}^{( 0 )} = [ {c}_{0}^{( 0 )} , {c}_{1}^{( 0 )} , {c}_{2}^{( 0 )} , {c}_{3}^{( 0 )} , {c}_{4}^{( 0 )} ] = [ {c}_{{R}_{0}^{( 0 )}} , {c}_{{R}_{1}^{( 0 )}} , {c}_{{R}_{2}^{( 0 )}} , {c}_{{R}_{3}^{( 0 )}} , {c}_{{R}_{4}^{( 0 )}} ] = [ {c}_{0} , {c}_{1} , {c}_{2} , {c}_{4} , {c}_{3} ]$$

the 1^{st} component repetition output bit sequence

$${c}^{( 1 )} = [ {c}_{0}^{( 1 )} , {c}_{1}^{( 1 )} ] = [ {c}_{{R}_{0}^{( 1 )}} , {c}_{{R}_{1}^{( 1 )}} ] = [ {c}_{0} , {c}_{5} ]$$

and the 2^{nd} component repetition output bit sequence

$${c}^{( 2 )} = [ {c}_{0}^{( 2 )} ] = [ {c}_{{R}_{0}^{( 2 )}} ] = [ {c}_{4} ] .$$

In some embodiment, the repetition comprises obtaining, by the first node, an input bit sequence c=[c₀, c₁, . . . , c_{K-1}] of length K; and performing, by the first node, an adding-frozen-bits operation on the input bit sequence c=[c₀, c₁, . . . , c_{K-1}] using the first data bit index set Q to obtain a repetition rate profile output bit sequence v′=[v′₀, v′₁, . . . , v′_{N-1}] of length N as in Algorithm 1 of TABLE 2; and determining, by the first node, the H component repetition output bit sequences c⁽⁰⁾, c⁽¹⁾, . . . , c^{(H-1)} by at least one of the following: the first data bit index set Q={Q₀, Q₁, . . . , Q_{K-1}}, the H component repetition lengths K₀, K₁, . . . , K_{H-1}.

TABLE 2
Algorithm 1

```
k = 0;
For i = 0 to N-1
  If i ∈ Q
    v′ᵢ = cₖ;
    k = k + 1;
  Else
    v′ᵢ = 0;
  End if
End for
```

Here, for h=0, 1, . . . , H−1, the h-th component repetition output bit sequences c^{(h)}=[c₀^{(h)}, c₁^{(h)}, . . . , c_{K}_{ₕ}₋₁^{(h)}] is of length Kₕ.

In some embodiments, for h=0, 1, . . . , H−1, the repetition determines the h-th component repetition output bit sequences c^{(h)} by setting the k-th bit cₖ^{(h)} in the h-th component repetition output bit sequences c^{(h)} to the bit with an index Qₖ in the repetition rate profile output bit sequence v′=[v′₀, v′₁, . . . , v′_{N-1}], i.e., cₖ^{(h)}=v′_{Q}_{ₖ}, wherein a pseudo-code is as follows.

```
For h = 0 to H-1
  For k = 0 to Kₕ-1
    cₖ^{(h)} = v′_{Q}_{ₖ};
  End for
End for
```

In a first specific example with K=6, an input bit sequence c=[c₀, c₁, c₂, c₃, c₄, c₅], H=2 polar matrix sizes N₀=16 and N₁=8, a first data bit index set Q={12, 7, 11, 13, 14, 15}, K₀=6, K₁=3, we obtain a repetition rate profile output bit sequence v′=[v′₀, v′₁, . . . , v′_{N-1}][v′₀, v′₁, v′₂, v′₃, v′₄, v′₅, v′₆, v′₇, v′₈, v′₉, v′₁₀, v′₁₁, v′₁₂, v′₁₃, v′₁₄, v′₁₅] of length N=max(N₀, N₁)=16, then we obtain the 0th component repetition output bit sequence c⁽⁰⁾=[c₀⁽⁰⁾, c₁⁽⁰⁾, c₂⁽⁰⁾, c₃⁽⁰⁾, c₄⁽⁰⁾, c₅⁽⁰⁾]=[v′_{Q}_{₀}, v′_{Q}_{₁}, v′_{Q}_{₂}, v′_{Q}_{₃}, v′_{Q}_{₄}, v′_{Q}_{₅}]=[v′₁₂, v′₇, v′₁₁, v′₁₃, v′₁₄, v′₁₅] and the 1^{st} component repetition output bit sequence c⁽¹⁾=[c₀⁽¹⁾, c₁⁽¹⁾, c₂⁽¹⁾]=[v′_{Q}_{₀}, v′_{Q}_{₁}, v′_{Q}_{₂}]=[v′₁₂, v′₇, v′₁₁].

In some embodiments, at least two of H repetition output bit sequences c⁽⁰⁾, c⁽¹⁾, . . . , c^{(H-1)} comprises the Qₖ-th bit v′_{Q}_{ₖ} in the repetition rate profile output bit sequence v′=[v′₀, v′₁, . . . , v′_{N-1}] of length N, wherein k is non-negative integer smaller than the size of the first data bit index set Q; Qₖ is the k-th element in the first data bit index set Q.

A specific example is all repetition output bit sequences c⁽⁰⁾, c⁽¹⁾, c^{(H-1)} comprises the Q₀-th bit v′_{Q}_{₀} in the repetition rate profile output bit sequence v′=[v′₀, v′₁, . . . , v′_{N-1}] of length N, wherein a specific example is c₀⁽⁰⁾=c₀⁽¹⁾=c₀^{(H-2)}=c₀^{(H-1)}=v′_{Q}_{₀}.

In some embodiments, at least two of H repetition output bit sequences c⁽⁰⁾, c⁽¹⁾, . . . , c^{(H-1)} comprises the k-th bit cₖ in the input bit sequence c=[c₀, c₁, . . . , c_{K-1}] of length K. A specific example is all repetition output bit sequences c⁽⁰⁾, c⁽¹⁾, c^{(H-1)} comprises the 0-th bit c₀ in the input bit sequence c=[c₀, c₁, . . . , c_{K-1}] of length K, wherein a specific example is c₀⁽⁰⁾=c₀⁽¹⁾= . . . =c₀^{(H-2)}=c₀^{(H-1)}=c₀.

In some embodiments, at least two of H repetition output bit sequences c⁽⁰⁾, c⁽¹⁾, . . . , c^{(H-1)} are of the same length, i.e., there exists h≠k such that Kₕ=Kₖ, wherein for h=0, 1, . . . , H−1, Kₕ is the length of the h-th repetition output bit sequences c^{(h)}. A specific example with H=3, all repetition output bit sequences c⁽⁰⁾, c⁽¹⁾, c⁽²⁾ are of length K₀=K₁=K₂=2.

In some embodiments, not all repetition output bit sequences c⁽⁰⁾, c⁽¹⁾, . . . , c^{(H-1)} are of the same length, i.e., there exists h≠k such that Kₕ≠Kₖ, wherein Kₕ is the length of the h-th repetition output bit sequences c^{(h)} and Kₖ is the length of the k-th repetition output bit sequences c^{(k)}. A specific example with H=3, the 0-th repetition output bit sequence c⁽⁰⁾ is of length K₀=6 and the 1^{st} repetition output bit sequence c⁽¹⁾ is of length K₁=3, wherein K₀≠K₁.

In some embodiments, all repetition output bit sequences c⁽⁰⁾, c⁽¹⁾, . . . , c^{(H-1)} are of different lengths, i.e., if h≠k, Kₕ≠Kₖ, wherein Kₕ is the length of the h-th repetition output bit sequences c^{(h)} and Kₖ is the length of the k-th repetition output bit sequences c^{(k)}. A specific example with H=3, the 0-th repetition output bit sequence c⁽⁰⁾ is of length K₀=6, the 1^{st} repetition output bit sequence c⁽¹⁾ is of length K₁=3, and the 2^{nd} repetition output bit sequence c⁽²⁾ is of length K₂=1, wherein K₀≠K₁, K₀≠K₂, and K₁≠K₂.

### Embodiment 16

This section discloses examples involving output bit sequence comprises both component interleaving output bit sequences and component polar coding output bit sequences.

Embodiment 16 is based on the above embodiments.

In some embodiments, for h=0, 1, . . . , W−1, the h-th concatenation input bit sequence x^{(h)} is the h-th component interleaving output bit sequence d′^{(h)}=[d′₀^{(h)}, d′₁^{(h)}, . . . , d′_{N}_{ₕ}₋₁^{(h)}] of length Nₕ while for h=W, W+1, . . . , H−1, the h-th concatenation input bit sequence x^{(h)} is the h-th component polar coding output bit sequence d^{(h)}=[d₀^{(h)}, d₁^{(h)}, . . . , d_{N}_{ₕ}₋₁^{(h)}], wherein Nₕ is the h-th component polar matrix size; W is the number of component interleaver patterns or the number of component interleaving; H is the number of component polar matrices. In some embodiments, the output bit sequence e=[e₀, e₁, . . . , e_{E-1}] comprises both component interleaving output bit sequences d′^{(h)} for some h's and component polar coding output bit sequences d^{(h)} for the rest h's, wherein, the h-th component interleaving output bit sequence d′^{(h)}=[d′₀^{(h)}, d′₁^{(h)}, . . . , d′_{N}_{ₕ}₋₁^{(h)}] is of length equal to the h-th component polar matrix size Nₕ; the h-th component polar coding output bit sequence d^{(h)}=[d₀^{(h)}, d₁^{(h)}, . . . , d_{N}_{ₕ}₋₁^{(h)}] is of length equal to the h-th component polar matrix size Nₕ. In a specific example, the output bit sequence e=[e₀, e₁, . . . , e_{E-1}] is a concatenation of W component interleaving output bit sequence d′⁽¹⁾, d′⁽²⁾, . . . , d′^{(W-1)} and H-W component polar coding output bit sequences d^{(W)}, d_{(W+1)}, . . . , d^{(H-1)} as follows:

$$[ {e}_{0} , {e}_{1} , {e}_{2} , ... , {e}_{E - 1} ] = [ {d}^{′ ( 0 )} , {d}^{′ ( 1 )} , ... , {d}^{′ ( W - 1 )} , {d}^{( W )} , {d}^{( W + 1 )} , ... , \\ {d}^{( H - 1 )} ] = [ {d}_{0}^{′ ( 0 )} , {d}_{1}^{′ ( 0 )} , … , {d}_{{N}_{0} - 1}^{′ ( 0 )} , … , {d}_{0}^{′ ( W - 1 )} , {d}_{1}^{′ ( W - 1 )} , … , {d}_{{N}_{W - 1} - 1}^{′ ( W - 1 )} , \\ … , {d}_{0}^{( W )} , {d}_{1}^{( W )} , … , {d}_{{N}_{W} - 1}^{( W )} … , {d}_{0}^{( H - 1 )} , {d}_{1}^{( H - 1 )} , … , {d}_{{N}_{H - 1} - 1}^{( H - 1 )} ] .$$

FIG. 4E gives a specific example for the output bit sequence e being a concatenation of component interleaving output bit sequences and component polar coding output bit sequences.

### Embodiment 17

This section discloses examples involving output bit sequence comprises both component interleaving output bit sequences and component pre-transformed polar coding output bit sequences.

Embodiment 17 is based on the above embodiments.

In some embodiments, for h=0, 1, . . . , W−1, the h-th concatenation input bit sequence x^{(h)} is the h-th component interleaving output bit sequence d′^{(h)}=[d′₀^{(h)}, d′₁^{(h)}, . . . , d′_{N}_{ₕ}₋₁^{(h)}] of length Nₕ while for h=W, W+1, . . . , H−1, the h-th concatenation input bit sequence x^{(h)} is the h-th component pre-transformed polar coding output bit sequence d^{(h)}=[d₀^{(h)}, d₁^{(h)}, . . . , d_{N}_{ₕ}₋₁^{(h)}], wherein Nₕ is the h-th component polar matrix size. In some embodiments, the output bit sequence e=[e₀, e₁, . . . , e_{E-1}] comprises both component interleaving output bit sequences d′^{(h)} for some h's and component pre-transformed polar coding output bit sequence d^{(h)} for the rest h's, wherein, the h-th component interleaving output bit sequence d′^{(h)}=[d′₀^{(h)}, d′₁^{(h)}, . . . , d′_{N}_{ₕ}₋₁^{(h)}] is of length equal to the h-th component polar matrix size Nₕ; the h-th component pre-transformed polar coding output bit sequence d^{(h)}=[d₀^{(h)}, d₁^{(h)}, . . . , d_{N}_{ₕ}₋₁^{(h)}] is of length equal to the h-th component polar matrix size Nₕ. In a specific example, the output bit sequence e=[e₀, e₁, . . . , e_{E-1}] is a concatenation of W component interleaving output bit sequences d′⁽⁰⁾, d′⁽¹⁾, . . . , d′^{(W-1)} and H-W component pre-transformed polar coding output bit sequences d^{(W)}, d^{(W+1)}, . . . , d^{(H-1)} as follows:

$$[ {e}_{0} , {e}_{1} , {e}_{2} , ... , {e}_{E - 1} ] = [ {d}^{′ ( 0 )} , {d}^{′ ( 1 )} , ... , {d}^{′ ( W - 1 )} , {d}^{( W )} , {d}^{( W + 1 )} , ... , \\ {d}^{( H - 1 )} ] = [ {d}_{0}^{′ ( 0 )} , {d}_{1}^{′ ( 0 )} , … , {d}_{{N}_{0} - 1}^{′ ( 0 )} , … , {d}_{0}^{′ ( W - 1 )} , {d}_{1}^{′ ( W - 1 )} , … , {d}_{{N}_{W - 1} - 1}^{′ ( W - 1 )} , \\ … , {d}_{0}^{( W )} , {d}_{1}^{( W )} , … , {d}_{{N}_{W} - 1}^{( W )} … , {d}_{0}^{( H - 1 )} , {d}_{1}^{( H - 1 )} , … , {d}_{{N}_{H - 1} - 1}^{( H - 1 )} ] .$$

FIG. 4F gives a specific example for the output bit sequence e being a concatenation of component interleaving output bit sequences and component pre-transformed polar coding output bit sequences.

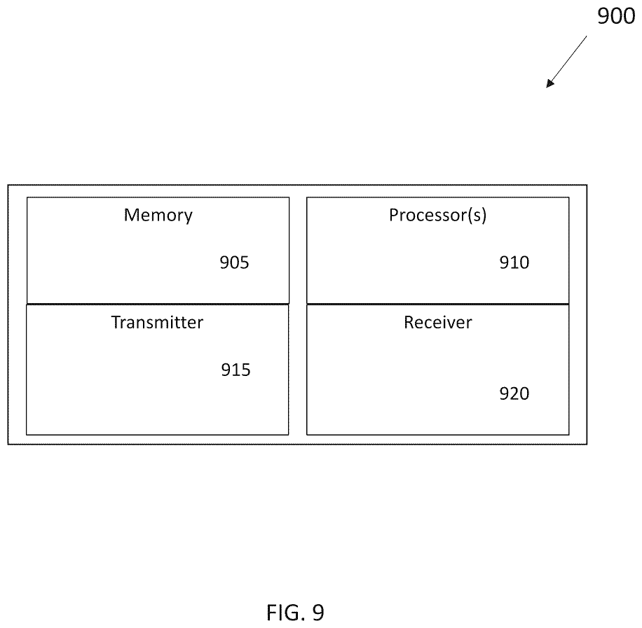

FIG. 9 shows an exemplary block diagram of a hardware platform 900 that may be a part of a network device (e.g., base station) or a communication device (e.g., a user equipment (UE)). The hardware platform 900 includes at least one processor 910 and a memory 905 having instructions stored thereupon. The instructions upon execution by the processor 910 configure the hardware platform 900 to perform the operations described in FIGS. 1 to 8 and in the various embodiments described in this patent document. The transmitter 915 transmits or sends information or data to another device. For example, a network device transmitter can send a message to user equipment. The receiver 920 receives information or data transmitted or sent by another device. For example, user equipment can receive a message from a network device.

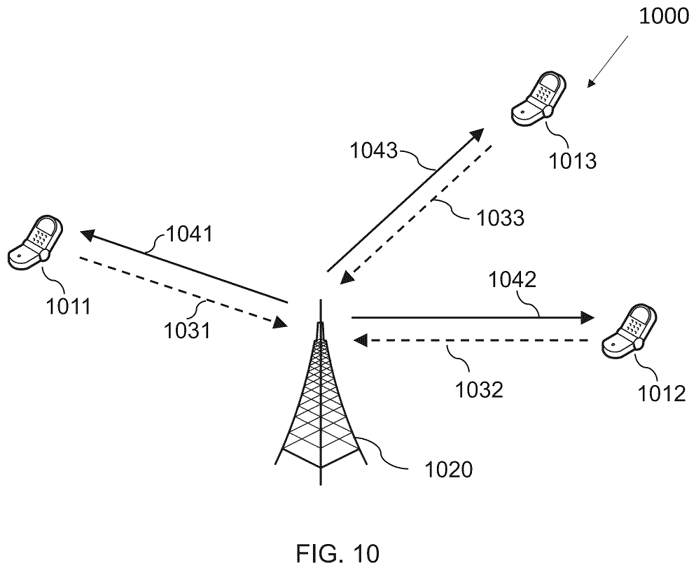

The implementations as discussed above will apply to a network communication. FIG. 10 shows an example of a communication system (e.g., a 5G or NR cellular network) that includes a base station 1020 and one or more user equipment (UE) 1011, 1012 and 1013. In some embodiments, the UEs access the BS (e.g., the network) using a communication link to the network (sometimes called uplink direction, as depicted by dashed arrows 1031, 1032, 1033), which then enables subsequent communication (e.g., shown in the direction from the network to the UEs, sometimes called downlink direction, shown by arrows 1041, 1042, 1043) from the BS to the UEs. In some embodiments, the BS send information to the UEs (sometimes called downlink direction, as depicted by arrows 1041, 1042, 1043), which then enables subsequent communication (e.g., shown in the direction from the UEs to the BS, sometimes called uplink direction, shown by dashed arrows 1031, 1032, 1033) from the UEs to the BS. The UE may be, for example, a smartphone, a tablet, a mobile computer, a machine to machine (M2M) device, an Internet of Things (IoT) device, and so on.

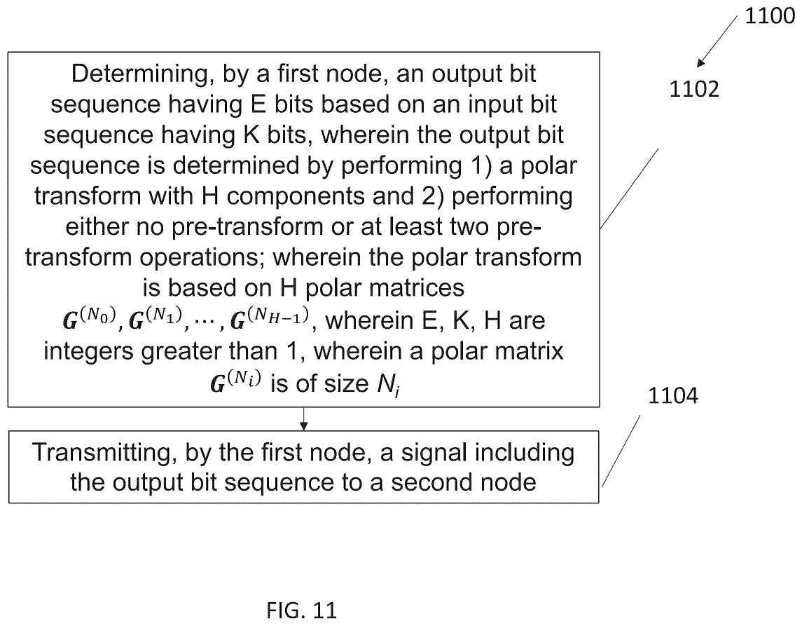

FIG. 11 shows an example flowchart representation of a method for digital communication in accordance with one or more embodiments of the present technology. Operation 1102 includes determining, by a first node, an output bit sequence having E bits based on an input bit sequence having K bits, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1)}}, wherein H, K and E are integers greater than 1, wherein a polar matrix G^{(N}^{ᵢ}⁾ is of size Nᵢ. Operation 1104 includes transmitting, by the first node, a signal including the output bit sequence to a second node.

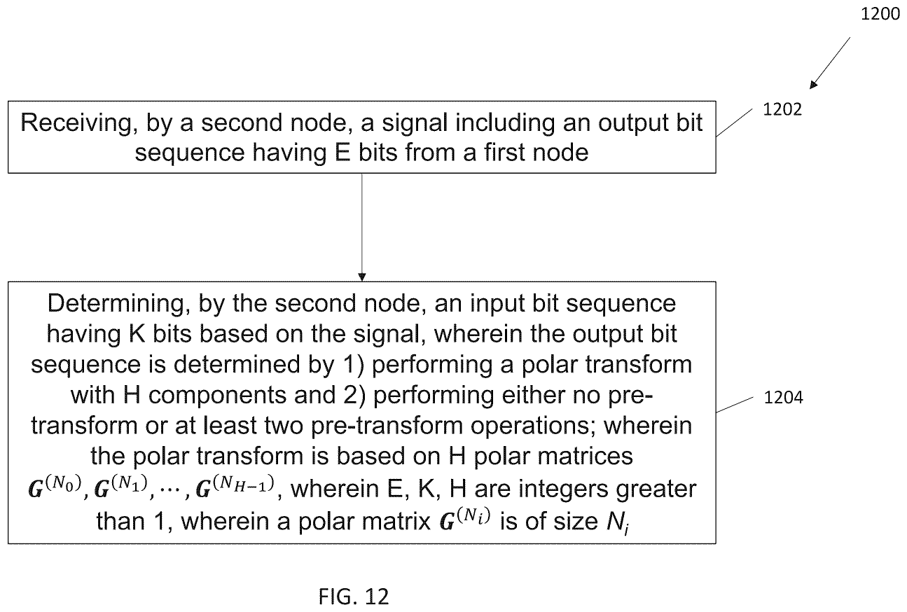

FIG. 12 shows another example flowchart representation of a method for digital communication in accordance with one or more embodiments of the present technology Operation 1202 includes receiving, by a second node, a signal including an output bit sequence having E bits from a first node. Operation 1204 includes determining, by the second node, an input bit sequence having K bits based on the output bit sequence, wherein the output bit sequence is determined by 1) performing a polar transform with H components and 2) performing either no pre-transform or at least two pre-transform operations; wherein the polar transform is based on H polar matrices G^{(N}^{₀}⁾, G^{(N}^{₁}⁾, . . . , G^{(N}^{_{H−1}}⁾, wherein H, K and E are integers greater than 1, wherein a polar matrix G^{(N}^{ᵢ}⁾ is of size Nᵢ.

Various preferred embodiments and additional features of the above-described methods of FIGS. 11 and 12 are as follows. Further examples are described with reference to embodiments 1 to 17.

In some embodiments, at least two of the H polar matrices have different sizes. In some embodiments, at least two of the H polar matrices are different. In some embodiments, at least two of the H polar matrices have sizes greater than 2.

In some embodiments N₀, N₁, . . . , N_{H-1} and E satisfy N₀+N₁+ . . . +N_{H-1}=E. In some embodiments each of N₀, N₁, . . . , N_{H-1} is an integer being a power of 2.

In some embodiments the output bit sequence is determined by further performing a repetition operation, wherein the input of the repetition operation is based on the input bit sequence. In some embodiments the repetition operation comprising: obtaining, by the first node, a repetition input bit sequence; and determining, by the first node, H component repetition output bit sequences c⁽⁰⁾, c⁽¹⁾, . . . , c^{(H-1)} based on at least one of: 1) a length list (K₀, K₁, . . . , K_{H-1}), wherein Kᵢ indicating the length of c⁽ⁱ⁾ or 2) a repetition index list (R⁽⁰⁾, R⁽¹⁾, . . . , R^{(H-1)}), wherein c⁽ⁱ⁾=[c₀⁽ⁱ⁾, c₁⁽ⁱ⁾, . . . , c_{K}_{ᵢ}₋₁⁽ⁱ⁾] and Kᵢ is a positive integer. In some embodiments, at least two of the H component repetition output bit sequences share at least one common element. In some embodiments, at least one of the H component repetition output bit sequences c⁽⁰⁾, c⁽¹⁾, . . . , c^{(H-1)} has a length equal to the length of the input bit sequence. In some embodiments at least two of the H component repetition output bit sequences c⁽ⁱ⁾ and c^{(j)} are determined based on at least one same bit in the input bit sequence. In some embodiments, at least two of the H component repetition output bit sequences c⁽ⁱ⁾ and c^{(j)} comprise common sub-sequences in the input bit sequence.

In some embodiments, at least two of the H component repetition output bit sequences c⁽ⁱ⁾ and c^{(j)} comprise matching sub-sequences generated based on the input bit sequence. In one example, an input bit sequence c=[c₀, c₁, c₂, c₃, c₄, c₅, c₆, c₇, c₈], c⁽ⁱ⁾=[c₀, c₁, c₇, c₃] and c^{(j)}=[c₃, c₂, c₇, c₅]. Here, c⁽ⁱ⁾ and c^{(j)} have matching subsequences [c₇, c₃] and [c₃, c₇] accordingly. Both matching subsequences are generated based on the input sequence c, i.e., the elements c₃ and c₇ are in the input sequence c. Also, the two subsequences [c₇, c₃] and [c₃, c₇] have a matching relationship, e.g., the third and fourth elements in c⁽ⁱ⁾ (c₇ and c₃) determine the third and first elements (c₇ and c₃) in c^{(j)}. The two matching subsequences do not need to be in the same order with each other. Also, the elements in a matching subsequence do not need to be in consecutive positions in c⁽ⁱ⁾ or c^{(j)}.

In some embodiments at least one element R⁽ⁱ⁾ in the repetition index list (R⁽⁰⁾, R⁽¹⁾, . . . , R^{(H-1)}) is equal to a first-type integer set Z_{K}={0, 1, 2, . . . , K−1}, wherein the first-type integer set Z_{K}={0, 1, 2, . . . , K−1} comprises all non-negative integers smaller than K.

In some embodiments, the output bit sequence is determined by further performing a rate profile operation, wherein the input of the rate profile operation is based on the input bit sequence. In some embodiments, the rate profile operation is performed on an input bit sequence c=[c₀, c₁, . . . , c_{K-1}] using a first data bit index set Q={Q₀, Q₁, . . . , Q_{K-1}} to obtain a repetition rate profile output bit sequence v′=[v′₀, v′₁, . . . , v′_{N-1}].

In some embodiments, the output bit sequence is determined by further performing a repetition operation, wherein the repetition operation comprises: determining, by the first node, H component repetition output bit sequences c⁽⁰⁾, c⁽¹⁾, . . . , c^{(H-1)} based on the repetition rate profile output bit sequence v′=[v′₀, v′₁, . . . , v′_{N-1}] by at least one of: 1) a length list (K₀, K₁, . . . , K_{H-1}), wherein Kᵢ indicating the length of c⁽ⁱ⁾ or 2) the first data bit index set Q={Q₀, Q₁, . . . , Q_{K-1}}, wherein c⁽ⁱ⁾=[c₀⁽ⁱ⁾, c₁⁽ⁱ⁾, . . . , c_{K}_{ᵢ}₋₁⁽ⁱ⁾]. In some embodiments, at least two of the H component repetition output bit sequences share at least one common element. In some embodiments, at least one of the H component repetition output bit sequences c⁽⁰⁾, c⁽¹⁾, . . . , c^{(H-1)} has a length equal to the length of the input bit sequence. In some embodiments, at least two of the H component repetition output bit sequences c⁽ⁱ⁾ and c^{(j)} are determined based on at least one same bit in the repetition rate profile output bit sequence v′=[v′₀, v′₁, . . . , v′_{N-1}], where N is an integer larger than 1. In some embodiments, at least two of the H component repetition output bit sequences c⁽ⁱ⁾ and c^{(j)} comprise common sub-sequences in the repetition rate profile output bit sequence v′=[v′₀, v′₁, . . . , v′_{N-1}], where N is an integer larger than 1

In some embodiments, at least two of the H component repetition output bit sequences c⁽ⁱ⁾ and c^{(j)} comprise matching sub-sequences generated based on the repetition rate profile output bit sequence v′=[v′₀, v′₁, . . . , v′_{N-1}], where N is an integer larger than 1. In one example, a repetition rate profile output bit sequence v′=[v′₀, v′₁, v′₂, v′₃, v′₄, v′₅, v′₆, v′₇], c⁽ⁱ⁾=[v′₀, v′₁, v′₂] and c^{(j)}=[v′₂, v′₁, v′₄]. Here, c⁽ⁱ⁾ and c^{(j)} have matching subsequences [v′₁, v′₂] and [v′₂, v′₁] accordingly. Both matching subsequences are generated based on the repetition rate profile output bit sequence v′, i.e., the elements v′₁ and v′₂ are in the repetition rate profile output bit sequence v′. Also, the two subsequences [v′₁, v′₂] and [v′₂, v′₁] have a matching relationship, e.g., the second and third elements in c (v′₁ and v′₂) map to the second and first elements (v′₁ and v′₂) in c^{(j)}. The two matching subsequences do not need to be in the same order with each other. Also, the elements in a matching subsequence do not need to be in consecutive positions in c⁽ⁱ⁾ or c^{(j)}.

In some embodiments, the first data bit index set Q={Q₀, Q₁, . . . , Q_{K-1}} is sorted according to index values or reliability of polarized sub-channels.

In some embodiments, the rate profile operation is performed with H components. In some embodiments, an h-th component of the rate profile operation is performed based on a component data bit index set Q^{(h)}={Q₀^{(h)}, Q₁^{(h)} . . . , Q_{K}_{ₕ}^{(h)}}, wherein Kₕ is an input length of the h-th component of the rate profile operation.

In some embodiments, the above methods further comprising performing a concatenation operation, wherein the input of the concatenation operation is based on the input sequence. In some embodiments, the concatenation operation generates the output sequence having E bits.

In some embodiments, the concatenation operation is performed on a first H component bit sequences generated based on the input sequence. In some embodiments, each of the at least two pre-transform operations generates an intermediate bit sequence.

In some embodiments, a bit of the intermediate bit sequence is determined by a convolution bit sequence or a convolution polynomial. In some embodiments, the convolution bit sequence comprises a generator bit sequence g=[g₀, g₁, . . . , gₘ], or a recursive feedback bit sequence q=[q₀, q₁, . . . , qₘ], wherein m is a positive integer. In some embodiments, the convolution polynomial comprises a generator polynomial g(D)=g₀+g₁·D+ . . . +gₘ₋₁·D^{m-1}+gₘ·D^{m}, or a recursive feedback polynomial q(D)=q₀+q₁·D+ . . . +qₘ₋₁·D^{m-1}+qₘ·D^{m}, wherein m is a positive integer.

In some embodiments, the at least two pre-transform operations are conducted with H components and generate H intermediate bit sequences. In some embodiments, H intermediate bit sequences are determined by H convolution bit sequences or H convolution polynomials. In some embodiments, H convolution bit sequences are H generator bit sequences g⁽⁰⁾, g⁽¹⁾, . . . , g^{(H-1)}, or H recursive feedback bit sequences q⁽⁰⁾, q⁽¹⁾, . . . , q^{(H-1)}; wherein for h=0, 1, . . . , H−1, g^{(h)}=[g^{(h)}₀, g^{(h)}₁, . . . , g^{(h)}ₘ] or q^{(h)} [q^{(h)}₀, q^{(h)}₁, . . . , q^{(h)}ₘ]. In some embodiments, H convolution polynomials comprise H generator polynomials g⁽⁰⁾(D), g⁽¹⁾(D), . . . , g^{(H-1)}(D), or H recursive feedback polynomials q⁽⁰⁾(D), q⁽¹⁾(D), . . . , q^{(H-1)}(D); wherein for h=0, 1, . . . , H−1, g^{(h)}(D)=g^{(h)}₀+g^{(h)}₁·D+ . . . +g(h)ₘ₋₁·D^{m-1}+g^{(h)}ₘ·D^{m} or q^{(h)}(D)=q^{(h)}₀+q^{(h)}₁·D+ . . . +q^{(h)}ₘ₋₁·D^{m-1}+q^{(h)}ₘ·D^{m}.

In some embodiments, the output bit sequence is determined further by performing an interleaving operation, wherein the input of the interleaving operation is based on the input bit sequence. In some embodiments, the interleaving operation is performed with W components, wherein W is an integer less than or equal to H. In some embodiments, the interleaving operation of any of the W components is determined by an interleaving pattern J^{(h)}=[J₀^{(h)}, J₁^{(h)}, . . . , J_{N}_{ₕ}₋₁^{(h)}] of length Nₕ, wherein Nₕ is an integer larger than 1.

It will be appreciated that the present document discloses methods and apparatus related to rate matching schemes applying to polar coding, PAC coding, or other pre-transformed polar coding. In 5G mobile communications standard of 3GPP, low-density parity-check (LDPC) codes are used for data transmission. However, LDPC has certain drawbacks compared to polar codes in short payload size (also called transport block size (TBS)). Alternatively, PAC codes can achieve finite-length bounds in moderate decoding complexity. PAC codes have code lengths with power of 2 (N=2ⁿ with positive integer n) as polar codes. However, to efficiently transmitting a payload (or transport block (TB)) in different wireless channel environments, it does not always have a code length of N=2ⁿ in time and frequency resources allocated by a base station (BS). Therefore, rate matching schemes are needed for applying PAC codes in wireless communications.

The disclosed and other embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or a variation of a subcombination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A method for digital communication, comprising:
determining, by a first node, an output bit sequence having E bits based on an input bit sequence having K bits, wherein the output bit sequence is determined by 1) performing a polar transform with H components and 2) performing either no pre-transform or at least two pre-transform operations, wherein the polar transform is based on H polar matrices G^{(N}^{₀}⁾, G^{(N}^{₁}⁾, . . . , G^{(N}^{_{H−1}}⁾, wherein H, K and E are integers greater than 1, and wherein a polar matrix G^{(N}^{ᵢ}⁾ is of size Nᵢ; and
transmitting, by the first node, a signal including the output bit sequence to a second node.

2. The method of claim 1, wherein at least two of the H polar matrices have different sizes.

3. The method of claim 1, wherein N₀, N₁, . . . , N_{H-1}, and E satisfy N₀+N₁+ . . . +N_{H-1}=E.

4. The method of claim 1, wherein each of N₀, N₁, . . . , N_{H-1} is an integer being a power of 2.

5. The method of claim 1, wherein the output bit sequence is determined by further performing a repetition operation, wherein an input of the repetition operation is based on the input bit sequence, and wherein the repetition operation comprises:
obtaining, by the first node, a repetition input bit sequence; and
determining, by the first node, H component repetition output bit sequences c⁽⁰⁾, c⁽¹⁾, . . . , c^{(H-1)} by at least one of: 1) a length list (K₀, K₁, . . . , K_{H-1}), wherein K₁ indicating the length of c⁽ⁱ⁾ or 2) a repetition index list (R⁽⁰⁾, R⁽¹⁾, . . . , R^{(H-1)}.

6. The method of claim 5, wherein at least two of the H component repetition output bit sequences share at least one common element, and wherein at least one of the H component repetition output bit sequences c⁽⁰⁾, c⁽¹⁾, . . . , c^{(H-1)} has a length equal to the length of the input bit sequence.

7. The method of claim 5, wherein at least two of the H component repetition output bit sequences c⁽ⁱ⁾ and c^{(j)} are determined based on at least one same bit in the input bit sequence.

8. The method of claim 5, wherein at least two of the H component repetition output bit sequences c⁽ⁱ⁾ and c^{(j)} comprise matching sub-sequences generated based on the input bit sequence.

9. The method of claim 5, wherein at least one element R⁽ⁱ⁾ in the repetition index list (R⁽⁰⁾, R⁽¹⁾, . . . , R^{(H-1)}) is equal to a first-type integer set Z_{K}={0, 1, 2, . . . , K−1}, wherein the first-type integer set Z_{K}={0, 1, 2, . . . , K−1} comprises all non-negative integers smaller than K.

10. A method for digital communication, comprising:
receiving, by a second node, a signal including an output bit sequence having E bits from a first node; and
determining, by the second node, an input bit sequence having K bits based on the signal, wherein the output bit sequence is determined by 1) performing a polar transform with H components and 2) performing either no pre-transform or at least two pre-transform operations, wherein the polar transform is based on H polar matrices G^{(N}^{₀}⁾, G^{(N}^{₁}⁾, . . . , G^{(N}^{_{H−1}}⁾, wherein H, K and E are integers greater than 1, and wherein a polar matrix G^{(N}^{ᵢ}⁾ is of size Nᵢ.

11. The method of claim 10, wherein the output bit sequence is determined by further performing a rate profile operation, wherein an input of the rate profile operation is based on the input bit sequence, and, wherein the rate profile operation is performed on an input bit sequence c=[c₀, c₁, . . . , c_{K-1}] using a first data bit index set Q={Q₀, Q₁, . . . , Q_{K-1}} to obtain a repetition rate profile output bit sequence v′=[v′₀, v′₁, . . . , v′_{N-1}].

12. The method of claim 11, wherein the output bit sequence is determined by further performing a repetition operation, wherein the repetition operation comprises: determining, by the first node, H component repetition output bit sequences c⁽⁰⁾, c⁽¹⁾, . . . , c^{(H-1)} based on the repetition rate profile output bit sequence v′=[v′₀, v′₁, . . . , v′_{N-1}] by at least one of: 1) a length list (K₀, K₁, . . . , K_{H-1}), wherein Kᵢ indicating the length of c⁽ⁱ⁾ or 2) the first data bit index set Q={Q₀, Q₁, . . . , Q_{K-1}}, wherein c⁽ⁱ⁾=[c₀⁽ⁱ⁾, c₁⁽ⁱ⁾, . . . , c_{K}_{ᵢ}₋₁⁽ⁱ⁾].

13. The method of claim 12, wherein at least two of the H component repetition output bit sequences share at least one common element.

14. The method of claim 12, wherein at least one of the H component repetition output bit sequences c⁽⁰⁾, c⁽¹⁾, . . . , c^{(H-1)} has a length equal to the length of the input bit sequence.

15. The method of claim 12, wherein at least two of the H component repetition output bit sequences c⁽ⁱ⁾ and c^{(j)} are determined based on at least one same bit in the repetition rate profile output bit sequence v′=[v′₀, v′₁, . . . , v′_{N-1}], where N is an integer larger than 1, wherein at least two of the H component repetition output bit sequences c⁽ⁱ⁾ and c^{(j)} comprise matching sub-sequences generated based on the repetition rate profile output bit sequence v′=[v′₀, v′₁, . . . , v′_{N-1}], and where N is an integer larger than 1.

16. The method of claim 12, wherein the first data bit index set Q={Q₀, Q₁, . . . , Q_{K-1}} is sorted according to index values or reliability of polarized sub-channels.

17. The method of claim 11, wherein the rate profile operation is performed with H components, wherein an h-th component of the rate profile operation is performed based on a component data bit index set Q^{(h)}={Q₀^{(h)}, Q₁^{(h)}, Q₂^{(h)}, . . . , Q_{K}_{ₕ}^{(h)}}, and wherein Kₕ is an input length of the h-th component of the rate profile operation.

18. An apparatus for communication network, comprising: a processor configured to:
determine an output bit sequence having E bits based on an input bit sequence having K bits, wherein the output bit sequence is determined by 1) performing a polar transform with H components and 2) performing either no pre-transform or at least two pre-transform operations, wherein the polar transform is based on H polar matrices G^{(N}^{₀}⁾, G^{(N}^{₁}⁾, . . . , G^{(N}^{_{H−1}}⁾, wherein H, K and E are integers greater than 1, and wherein a polar matrix G^{(N}^{ᵢ}⁾ is of size Nz; and
transmit a signal including the output bit sequence to a second node.

19. The apparatus of claim 18, wherein the processor is further configured to perform a concatenation operation, wherein the input of the concatenation operation is based on the input sequence, wherein the concatenation operation generates the output sequence having E bits, and wherein the concatenation operation is performed on a first H component bit sequences generated based on the input sequence.

20. The apparatus of claim 18, wherein the output bit sequence is determined further by performing an interleaving operation, wherein an input of the interleaving operation is based on the input bit sequence, wherein the interleaving operation is performed on W components, wherein W is an integer less than or equal to H, and wherein the interleaving operation of any of the W components is determined by an interleaving pattern J^{(h)}=[J₀^{(h)}, J₁^{(h)}, . . . , J_{N}_{ₕ}₋₁^{(h)}] of length Nₕ, wherein Nₕ is an integer larger than 1.
